(19) United States
(12) Patent Application Publication
(10) Pub. No.: US 2023/0105289 A1
(43) Pub. Date: Apr. 6, 2023

(54) DISPLAY APPARATUS AND METHOD OF PROVIDING THE SAME

(71) Applicant: Samsung Display Co., Ltd., Yongin-si (KR)

(72) Inventors: Donghee Choi, Yongin-si (KR); Beomsoo Park, Yongin-si (KR); Wangjo Lee, Yongin-si (KR); Youngmin Kwon, Yongin-si (KR); Jinwhan Jung, Yongin-si (KR)

(21) Appl. No.: 17/846,842

(22) Filed: Jun. 22, 2022

(30) Foreign Application Priority Data
Oct. 5, 2021 (KR) 10-2021-0131965

(51) Int. Cl. H01L 27/32

(52) U.S. Cl. CPC H01L 27/3258; H01L 27/3276

(57) ABSTRACT

A display apparatus includes an insulating layer including a first portion including a first groove and a second portion which is adjacent to the first portion, a first conductive layer including a 1-1 conductive layer in the first groove of the interlayer insulating layer and a 1-2 conductive layer which is on the second portion, a first planarization layer on the first conductive layer and including a third portion including a second groove and a fourth portion which is adjacent to the third portion, and a second conductive layer including a 2-1 conductive layer in the second groove of the first planarization layer and a 2-2 conductive layer which is on the fourth portion.

This application claims priority to Korean Patent Application No. 10-2021-0131965, filed on Oct. 5, 2021, and all the benefits accruing therefrom under 35 U.S.C. § 119, the disclosure of which is incorporated by reference herein in its entirety.

### BACKGROUND

### 1. Field

One or more embodiments relate to a display apparatus and a method of providing (or manufacturing) the same.

### 2. Description of the Related Art

Display apparatuses are apparatuses that visually display data. Display apparatuses are used as displays of small products such as mobile phones and are also used as displays of large products such as televisions.

Display apparatuses include a plurality of pixels that receive an electrical signal and emit light in order to display an image to outside the display apparatuses. Each of the pixels includes a display element. For example, an organic light-emitting display apparatus includes an organic light-emitting diode as a display element. In general, the organic light-emitting display apparatus includes a thin-film transistor and an organic light-emitting diode on a substrate, and the organic light-emitting diode operates by self-emitting light.

As use of the display apparatuses has been diversified, various designs to improve quality have been attempted.

### SUMMARY

One or more embodiments include a display apparatus capable of preventing or reducing the occurrence of parasitic capacitance between wires, and a method of providing (or manufacturing) the display apparatus.

Technical problems to be solved are not limited to the above-described technical problems, and other unmentioned technical problems will be apparent to one of ordinary skill in the art from the description.

Additional aspects will be set forth in part in the description which follows and, in part, will be apparent from the description, or may be learned by practice of the presented embodiments of the disclosure.

According to one or more embodiments, a display apparatus includes an interlayer insulating layer including a first portion including a first groove and a second portion which is adjacent to the first portion, a first conductive layer including a 1-1 conductive layer in the first groove of the interlayer insulating layer and a 1-2 conductive layer which is on the second portion, a first planarization layer on the first conductive layer and including a third portion including a second groove and a fourth portion which is adjacent to the third portion, and a second conductive layer including a 2-1 conductive layer in the second groove of the first planarization layer and a 2-2 conductive layer which is on the fourth portion.

The 1-1 conductive layer may at least partially overlap the 2-2 conductive layer.

The 1-1 conductive layer and the 1-2 conductive layer may be integrally provided with each other.

The 2-1 conductive layer and the 2-2 conductive layer may be integrally provided with each other.

A distance from an upper surface of the 1-1 conductive layer to an upper surface of the first planarization layer, may be greater than a distance from an upper surface of the 1-2 conductive layer to the upper surface of the first planarization layer, in a direction vertical to the substrate.

The display apparatus may further include a second planarization layer on the second conductive layer, and a pixel electrode on the second planarization layer.

The 2-1 conductive layer may at least partially overlap the pixel electrode.

A distance from an upper surface of the 2-1 conductive layer to an upper surface of the second planarization layer, may be greater than a distance from an upper surface of the 2-2 conductive layer to the upper surface of the second planarization layer, in a direction vertical to the substrate.

The first groove and the second groove may not overlap each other in a direction vertical to the substrate.

The display apparatus may further include a first thin-film transistor including a first semiconductor layer and a first electrode which is at least partially overlapping the first semiconductor layer, and a capacitor including the first electrode and a second electrode which is at least partially overlapping the first electrode.

The interlayer insulating layer may cover the second electrode.

The display apparatus may further include a second thin-film transistor above the first thin-film transistor, and including a second semiconductor layer and a third electrode which is at least partially overlapping the second semiconductor layer.

The interlayer insulating layer may cover the third electrode.

The first semiconductor layer and the second semiconductor layer may include different materials from each other.

The first conductive layer may extend in a first direction, and the second conductive layer may extend in a second direction crossing the first direction.

According to one or more embodiments, a method of providing (or manufacturing) a display apparatus includes forming (or providing) an insulating layer, forming a first groove in the interlayer insulating layer, forming a first conductive layer on the interlayer insulating layer, where the first conductive layer includes a 1-1 conductive layer and a 1-2 conductive layer, forming a first planarization layer on the first conductive layer, forming a second groove in the first planarization layer, and forming a second conductive layer on the first planarization layer, where the second conductive layer includes a 2-1 conductive layer and a 2-2 conductive layer.

The forming of the first groove in the interlayer insulating layer may further include forming a photoresist pattern on the interlayer insulating layer, exposing the photoresist pattern to light by using a first halftone mask, developing the photoresist pattern exposed to light, etching the interlayer insulating layer, and removing the photoresist pattern.

The forming of the second groove in the first planarization layer may further include exposing the first planarization layer to light by using a second halftone mask, and developing the first planarization layer exposed to light, to form the second groove.

The interlayer insulating layer may include a first portion including the first groove and a second portion which is adjacent to the first portion, where the 1-1 conductive layer may be in the first groove, and the 1-2 conductive layer may be on the second portion.

The first planarization layer may include a third portion including the second groove and a fourth portion which is adjacent to the third portion, where the 2-1 conductive layer may be in the second groove, and the 2-2 conductive layer may be on the fourth portion.

The 1-1 conductive layer may at least partially overlap the 2-2 conductive layer.

The 1-1 conductive layer and the 1-2 conductive layer may be integrally provided with each other.

The 2-1 conductive layer and the 2-2 conductive layer may be integrally provided with each other.

A distance from an upper surface of the 1-1 conductive layer to an upper surface of the first planarization layer, may be greater than a distance from an upper surface of the 1-2 conductive layer to the upper surface of the first planarization layer, in a direction vertical to the substrate.

The method may further include, after the forming of the second conductive layer on the first planarization layer, forming a second planarization layer on the second conductive layer, and forming a pixel electrode on the second planarization layer.

The 2-1 conductive layer may at least partially overlap the pixel electrode.

A distance from an upper surface of the 2-1 conductive layer to an upper surface of the second planarization layer, may be greater than a distance from an upper surface of the 2-2 conductive layer to the upper surface of the second planarization layer, in a direction vertical to the substrate.

The first groove and the second groove may not overlap each other in a direction vertical to the substrate.

The first conductive layer may extend in a first direction, and the second conductive layer may extend in a second direction crossing the first direction.

The method may further include, before the forming of the interlayer insulating layer on the substrate, forming a first thin-film transistor on the substrate.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic plan view of a display apparatus according to an embodiment;

FIG. 2 is a schematic plan view of a display apparatus according to an embodiment;

FIGS. 3 and 4 are equivalent circuit diagrams of one pixel of a display apparatus according to embodiments;

FIG. 5 is a schematic plan view of a display apparatus according to an embodiment;

FIG. 6 is a schematic cross-sectional view of a display apparatus according to an embodiment;

FIG. 7 is a schematic cross-sectional view of a display apparatus according to an embodiment;

FIGS. 8 and 9 are schematic cross-sectional views of a display apparatus according to an embodiment; and

FIGS. 10 to 22 are schematic cross-sectional views of a method of providing (or manufacturing) a display apparatus, according to an embodiment.

### DETAILED DESCRIPTION

Reference will now be made in detail to embodiments, examples of which are illustrated in the accompanying drawings, where like reference numerals refer to like elements throughout. In this regard, the embodiments may have different forms and should not be construed as being limited to the descriptions set forth herein. Accordingly, the embodiments are merely described below, by referring to the figures, to explain aspects of the present description.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, embodiments will be illustrated in the drawings and described in the written description. Effects and features of one or more embodiments and methods of accomplishing the same will become apparent from the following detailed description of the one or more embodiments, taken in conjunction with the accompanying drawings. However, the embodiments may have different forms and should not be construed as being limited to the descriptions set forth herein.

While such terms as “first” and “second” may be used to describe various elements, such elements must not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being related to another element such as being “on” another layer, region, or element, it may be directly or indirectly on the other layer, region, or element. That is, for example, intervening layers, regions, or elements may be present. In contrast, when a layer, region, or element is referred to as being related to another element such as being “directly on” another layer, region, or element, no intervening layer, region, or element is present therebetween.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

As used herein, the expression “A and/or B” refers to A, B, or A and B. In addition, the expression “at least one of A and B” refers to A, B, or A and B.

In the following disclosure, when an element such as a wire is described as “extending in a first direction or a second direction,” the description covers not only a case where the wire extends in a straight line but also a case where the wire extends in a zigzag or curve in the first or second direction.

In the following disclosure, the phrase “in a plan view” indicates that a portion of a target object is seen from above or normal to a plane, and the phrase “in a cross-sectional view” indicates that a portion of a target object is vertically cut and the cross-section is viewed from the side. In the following disclosure, the term “overlap” covers overlapping “in a plan view” and overlapping “in a cross-sectional view”.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

One or more embodiments will be described below in more detail with reference to the accompanying drawings. Those elements that are the same or are in correspondence with each other are rendered the same reference numeral regardless of the figure number, and redundant descriptions thereof are omitted. As used herein, a reference number may indicate a singular element or a plurality of the element. For example, a reference number labeling a singular form of an element within the drawing figures may be used to reference a plurality of the singular element within the text of specification.

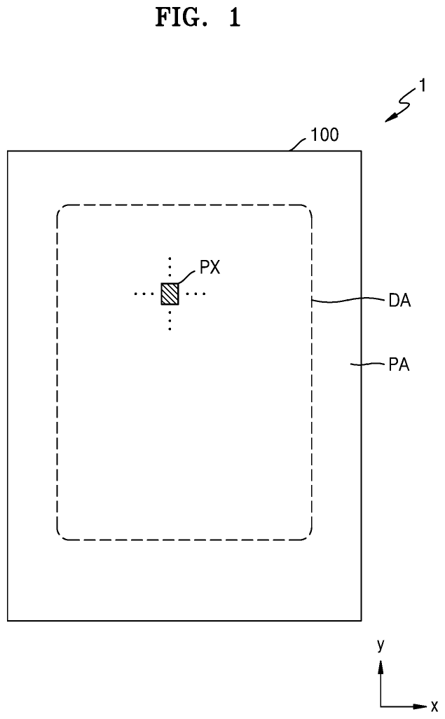

FIG. 1 is a schematic plan view of a display apparatus 1 according to an embodiment.

Referring to FIG. 1, the display apparatus 1 may include a display area DA displaying an image, and a peripheral area PA which is adjacent to the display area such as being arranged around the display area DA. The display apparatus 1 may provide an image to the outside by using light emitted from the display area DA. The display apparatus 1 includes a substrate 100, and accordingly, the substrate 100 may be stated to have the display area DA and the peripheral area PA. That is, various components or layers of the display apparatus 1 may include the display area DA and the peripheral area PA described herein.

The substrate 100 may include various materials such as glass, metal, or plastic. In an embodiment, the substrate 100 may include a flexible material. In this regard, the flexible material may be a material that may be curvable, bendable, foldable and/or rollable such as be curved, bent, folded and/or rolled (e.g., with relative ease). The substrate 100 including such a flexible material may include ultra-thin glass, metal, or plastic.

Pixels PX including various display elements such as an organic light-emitting diode OLED, may be arranged in the display area DA of the substrate 100. A pixel PX may be provided in plural and may include a plurality of pixels PX, and the plurality of pixels PX may be arranged in various patterns, such as a stripe arrangement, a Pentile arrangement, or a mosaic arrangement, to implement an image. Although the display apparatus 1 according to an embodiment is described below as including an organic light-emitting diode OLED, the disclosure is not limited thereto. In an embodiment, for example, the display apparatus 1 may include an inorganic light-emitting diode OLED, a quantum dot light-emitting diode, etc. Alternatively, an emission layer of a display element included in the display apparatus 1 may include at least one of an organic material, an inorganic material, and quantum dots.

Although FIG. 1 shows a planar shape of the display area DA being a rectangular shape, the disclosure is not limited thereto. In an embodiment, for example, the display area DA may have a polygonal planar shape, such as a triangle, a pentagon, or a hexagon, a circular shape, an oval shape, an irregular shape, or the like.

The peripheral area PA of the substrate 100 is an area arranged adjacent to the display area DA such as being around the display area DA, and may be an area displaying no image (e.g., non-display area). Various wires configured to transmit electrical signals to be applied to the display area DA, and pads to which a printed circuit board or a driver integrated circuit (IC) chip is attached, may be in the peripheral area PA.

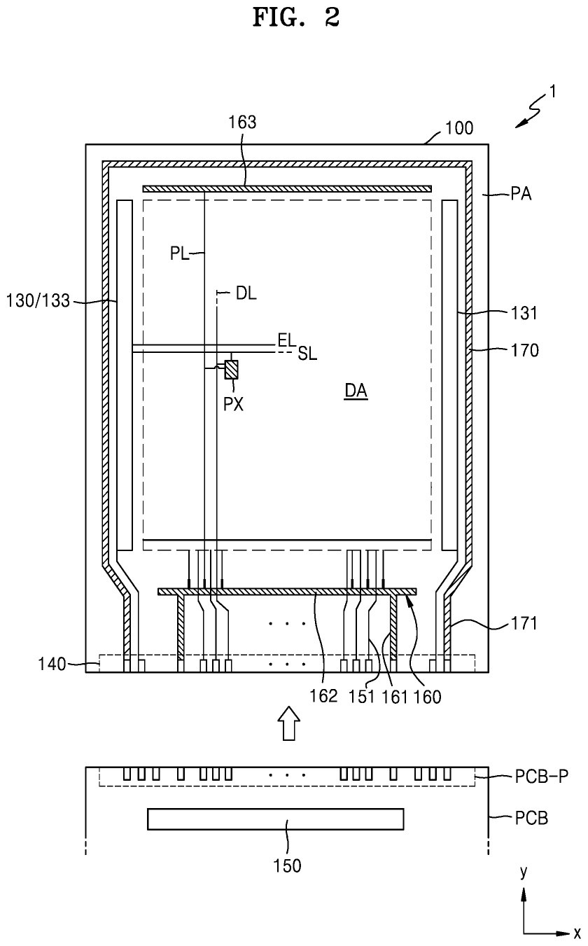

FIG. 2 is a schematic plan view of the display apparatus 1 according to an embodiment.

Referring to FIG. 2, the display apparatus 1 includes the display area DA and the peripheral area PA, and the plurality of pixels PX may be arranged in the display area DA. Each of the plurality of pixels PX may include a display element such as an organic light-emitting diode OLED. Each pixel PX may emit, for example, red, green, blue, or white light, via the organic light-emitting diode OLED. Hereinafter, in the present description, each pixel PX refers to a sub-pixel among sub-pixels which each emit light of a different color, and each pixel PX may be, for example, one of a red sub-pixel, a green sub-pixel, and a blue sub-pixel. The display area DA may be covered by an encapsulation member (not shown) and various components or layers within the display area DA may be protected from external air or moisture.

Each pixel PX may be electrically connected to outer circuits arranged in the peripheral area PA. A first scan driving circuit 130, a second scan driving circuit 131, an emission control driving circuit 133, a terminal 140, a data driving circuit 150, a first power supply line 160, and a second power supply line 170 may be arranged in the peripheral area PA.

The first scan driving circuit 130 and the second scan driving circuit 131 may provide a scan signal Sn to each pixel PX, via a scan line SL. The second scan driving circuit 131 may be parallel to the first scan driving circuit 130 with the display area DA therebetween. Some of the pixels PX arranged in the display area DA may be electrically connected to the first scan driving circuit 130, and the others may be electrically connected to the second scan driving circuit 131. However, the second scan driving circuit 131 may be omitted.

The emission control driving circuit 133 may provide an emission control signal Em to each pixel PX, via an emission control line EL. Although FIG. 2 shows the first scan driving circuit 130 and the emission control driving circuit 133 integrally provided with each other, the disclosure is not limited thereto. The first scan driving circuit 130 and the emission control driving circuit 133 may be provided independently of each other.

The terminal 140 (e.g., terminal area) may be arranged on a side of the substrate 100. The terminal area may include pads to which an external device is attached. The terminal 140 may be exposed to outside the display apparatus 1 without being covered by an insulating layer and may be electrically connected to an external device such as a printed circuit board PCB. The display apparatus 1 may be connected to the external device at the terminal 140. A terminal PCB-P of the printed circuit board PCB may be electrically connected to a pad within the terminal 140 of the display apparatus 1. The printed circuit board PCB may be configured to transmit a signal of a controller (not shown) or power to the display apparatus 1.

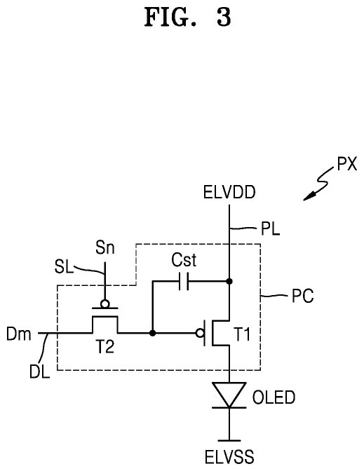

Control signals generated by the controller may be transmitted to the first scan driving circuit 130 and the second scan driving circuit 131, respectively, via the printed circuit board PCB. The controller may provide a first power voltage ELVDD (refer to FIG. 3) to the first power supply line 160 via a first connection line 161 and may provide a second power voltage ELVSS (refer to FIG. 3) to the second power supply line 170 via a second connection line 171.

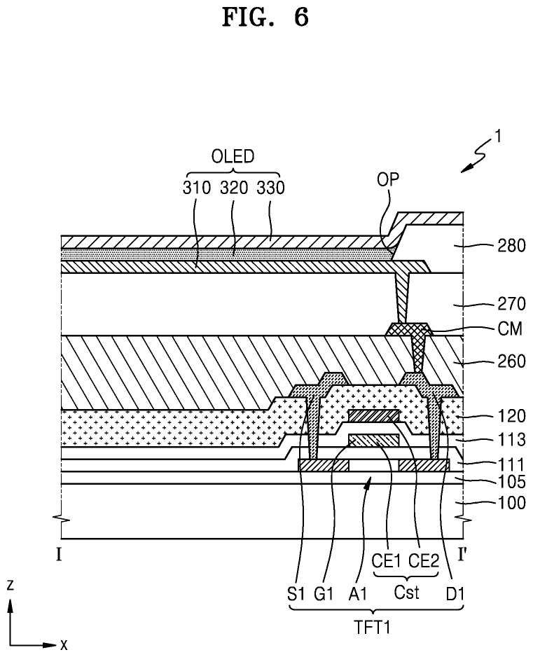

The first power voltage ELVDD may be provided to each pixel PX via a driving voltage line PL connected to the first power supply line 160, and the second power voltage ELVSS may be provided to an opposite electrode 330 (refer to FIG. 6) of each pixel PX connected to the second power supply line 170.

The data driving circuit 150 may be electrically connected to a data line DL. A data signal DM of the data driving circuit 150 may be provided to each pixel PX via a connection line 151 connected to the terminal 140 and the data line DL connected to the connection line 151. Although FIG. 2 shows the data driving circuit 150 arranged on the printed circuit board PCB, the disclosure is not limited thereto. In an embodiment, the data driving circuit 150 may be arranged on the substrate 100. In an embodiment, for example, the data driving circuit 150 may be arranged between the terminal 140 and the first power supply line 160.

The first power supply line 160 may include a first sub-line 162 and a second sub-line 163 each extending in a first direction (a direction x) and parallel to each other. The first sub-line 162 and the second sub-line 163 may be spaced apart from each other in a second direction (a direction y) with the display area DA therebetween. A plane may be defined by the first direction and the second direction crossing each other. A thickness direction may be defined along a third direction which crosses each of the first and second directions. The second power supply line 170 may partially surround the display area DA in a loop shape having one side open.

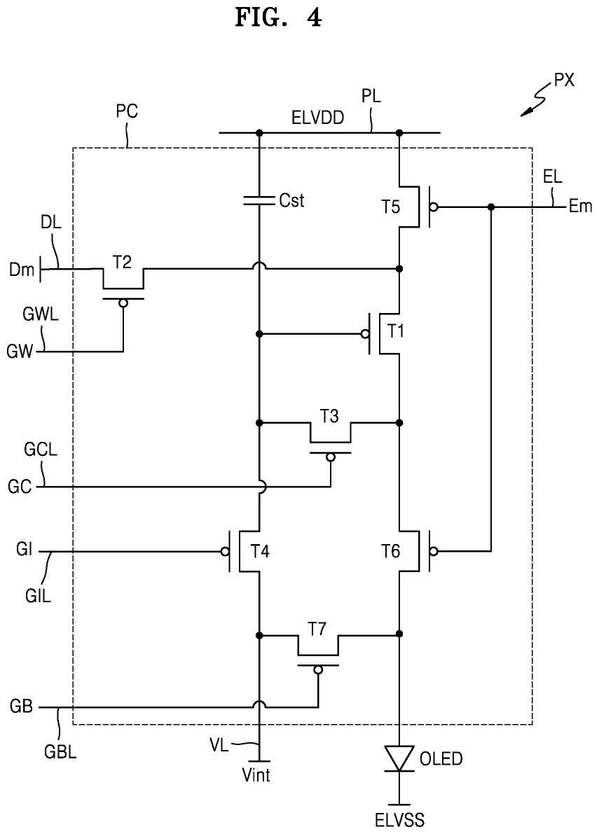

FIGS. 3 and 4 are equivalent circuit diagrams of one pixel PX of a display apparatus 1 according to an embodiment.

Referring to FIG. 3, each pixel PX may include a pixel circuit PC connected to the scan line SL and the data line DL, and an organic light-emitting diode OLED connected to the pixel circuit PC.

The pixel circuit PC may include a first transistor T1, a second transistor T2, and a capacitor Cst. The first transistor T1 may be a driving thin-film transistor, and the second transistor T2 may be a switching thin-film transistor. The second transistor T2 may be connected to the scan line SL and the data line DL and may be configured to transmit a data signal Dm input via the data line DL to the first transistor T1, according to a scan signal Sn input via the scan line SL.

The capacitor Cst may be connected to the second transistor T2 and the driving voltage line PL and may store a voltage corresponding to a difference between a voltage received from the second transistor T2 and the first power voltage ELVDD supplied to the driving voltage line PL.

The first transistor T1 may be connected to the driving voltage line PL and the capacitor Cst and may be configured to control a driving current (e.g., electrical current) flowing through the organic light-emitting diode OLED from the driving voltage line PL, in response to a voltage value stored in the capacitor Cst. The organic light-emitting diode OLED may emit light having a brightness according to the driving current.

Although FIG. 3 shows the pixel circuit PC including two transistors and one capacitor, the disclosure is not limited thereto. In an embodiment, for example, the pixel circuit PC may include three or more transistors and/or two or more capacitors.

Referring to FIG. 4, the pixel circuit PC may include the first transistor T1, the second transistor T2, a third transistor T3, a fourth transistor T4, a fifth transistor T5, a sixth transistor T6, a seventh transistor T7, and the capacitor Cst.

The second transistor T2, which is a switching thin-film transistor, may be connected to a first scan line GWL and the data line DL, and may be configured to transmit the data signal Dm (or a data voltage) input from the data line DL to the first transistor T1, based on a first scan signal GW input from the first scan line GWL. The capacitor Cst may be connected to the second transistor T2 and the driving voltage line PL and may store a voltage corresponding to a difference between a voltage received from the second transistor T2 and the first power voltage ELVDD supplied to the driving voltage line PL.

The first transistor T1, which is a driving thin-film transistor, may be connected to the driving voltage line PL and the capacitor Cst and may be configured to control a driving current flowing through the organic light-emitting diode OLED from the driving voltage line PL, in response to a voltage value stored in the capacitor Cst. The organic light-emitting diode OLED may emit light having a brightness according to the driving current. An opposite electrode 330 (e.g., a cathode) of the organic light-emitting diode OLED may receive the second power voltage ELVSS.

The third transistor T3 is a compensation thin-film transistor, and a gate electrode of the third transistor T3 may be connected to a second scan line GCL. A source electrode (or a drain electrode) of the third transistor T3 may be connected to a drain electrode (or a source electrode) of the first transistor T1 and may also be connected to a first electrode (e.g., an anode) of the organic light-emitting diode OLED via the sixth transistor T6. A drain electrode (or a source electrode) of the third transistor T3 may be connected to one electrode of the capacitor Cst, a source electrode (or a drain electrode) of the fourth transistor T4, and a gate electrode of the first transistor T1. The third transistor T3 may be turned on according to a second scan signal GC received via the second scan line GCL to diode-connect the first transistor T1 by connecting the gate electrode and the drain electrode of the first transistor T1 to each other.

The fourth transistor T4 is an initialization thin-film transistor, and a gate electrode of the fourth transistor T4 may be connected to a third scan line GIL. A drain electrode (or a source electrode) of the fourth transistor T4 may be connected to a voltage line VL. The source electrode (or the drain electrode) of the fourth transistor T4 may be connected to one electrode of the capacitor Cst, the drain electrode (or the source electrode) of the third transistor T3, and the gate electrode of the first transistor T1. The fourth transistor T4 may be turned on according to a third scan signal GI received via the third scan line GIL to perform an initialization operation for initializing a voltage of the gate electrode of the first transistor T1 by transmitting an initialization voltage Vint to the gate electrode of the first transistor T1.

The fifth transistor T5 is an operation control thin-film transistor, and a gate electrode of the fifth transistor T5 may be connected to the emission control line EL. A source electrode (or a drain electrode) of the fifth transistor T5 may be connected to the driving voltage line PL. A drain electrode (or a source electrode) of the fifth transistor T5 may be connected to a source electrode (or the drain electrode) of the first transistor T1 and a drain electrode (or the source electrode) of the second transistor T2.

The sixth transistor T6 is an emission control thin-film transistor, and a gate electrode of the sixth transistor T6 may be connected to the emission control line EL. A source electrode (or a drain electrode) of the sixth transistor T6 may be connected to the drain electrode (or the source electrode) of the first transistor T1 and the source electrode (or the drain electrode) of the third transistor T3. A drain electrode (or a source electrode) of the sixth transistor T6 may be electrically connected to a pixel electrode 310 (refer to FIG. 6) of the organic light-emitting diode OLED. As the fifth transistor T5 and the sixth transistor T6 are simultaneously turned on according to an emission control signal Em received via the emission control line EL, the first power voltage ELVDD is transmitted to the organic light-emitting diode OLED, and a driving current flows through the organic light-emitting diode OLED.

The seventh transistor T7 may be an initialization thin-film transistor configured to initialize the pixel electrode 310 of the organic light-emitting diode OLED. A gate electrode of the seventh transistor T7 may be connected to a fourth scan line GBL. A source electrode (or a drain electrode) of the seventh transistor T7 may be connected to the pixel electrode 310 of the organic light-emitting diode OLED. A drain electrode (or a source electrode) of the seventh transistor T7 may be connected to the voltage line VL. The seventh transistor T7 may be turned on according to a fourth scan signal GB received via the fourth scan line GBL to initialize the pixel electrode 310 of the organic light-emitting diode OLED.

Although FIG. 4 shows the fourth transistor T4 and the seventh transistor T7 respectively connected to the third scan line GIL and the fourth scan line GBL, the disclosure is not limited thereto. In an embodiment, for example, both of the fourth transistor T4 and the seventh transistor T7 may be connected to the third scan line GIL and driven according to the third scan signal GI.

One electrode of the capacitor Cst may be connected to the driving voltage line PL. The other electrode of the capacitor Cst may be connected to the gate electrode of the first transistor T1, the drain electrode (or the source electrode) of the third transistor T3, and the source electrode (or the drain electrode) of the fourth transistor T4 together.

The opposite electrode 330 of the organic light-emitting diode OLED may receive the second power voltage ELVSS. The organic light-emitting diode OLED may receive a driving current from the first transistor T1 and emit light.

In an embodiment, all of the first to seventh transistors T1 to T7 may include a semiconductor layer including silicon. However, the disclosure is not limited thereto.

In an embodiment, at least one of the first to seventh transistors T1 to T7 may include a semiconductor layer including oxide, and the other transistors may include a semiconductor layer including silicon. In more detail, the first transistor T1 directly affecting brightness of the display apparatus 1 is configured to include a silicon semiconductor formed of polycrystalline silicon having high reliability, and thus, a high-resolution display apparatus 1 may be implemented.

An oxide semiconductor has a high carrier mobility and a low leakage current, and accordingly, a voltage drop thereof is not great even when a driving period is relatively long. That is, a color change of an image due to a voltage drop is not great even during low-frequency driving, and accordingly, low-frequency driving may be performed. As described above, an oxide semiconductor has a low leakage current, and thus, at least one of the third transistor T3 and the fourth transistor T4 connected to the gate electrode of the first transistor T1 may include an oxide semiconductor to thereby prevent a leakage current that may flow to the gate electrode of the first transistor T1 and reduce power consumption. In this case, a conductive signal line and/or a conductive voltage line may be added to the pixel circuit PC of FIG. 4. In addition, another transistor besides the third transistor T3 and the fourth transistor T4 may include a semiconductor layer including oxide. In an embodiment, for example, the seventh transistor T7 may include a semiconductor layer including an oxide semiconductor.

Although FIG. 4 shows the pixel circuit PC including seven transistors and one capacitor, the disclosure is not limited thereto. The pixel circuit PC may include transistors and capacitors in a variety of numbers, and for example, may include eight transistors and one capacitor, may include nine transistors and one capacitor, or may include nine transistors and two capacitors.

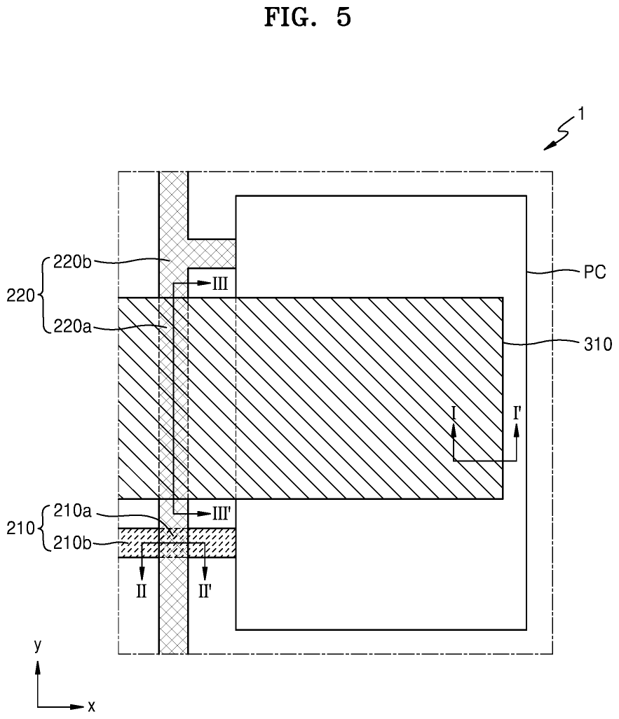

FIG. 5 is a schematic enlarged plan view of the display apparatus 1 according to an embodiment.

Referring to FIG. 5, the display apparatus 1 may include the pixel circuit PC, a first conductive layer 210, a second conductive layer 220, and the pixel electrode 310.

As described above with reference to FIG. 4, the pixel circuit PC may include seven transistors and one capacitor. However, the disclosure is not limited thereto. The pixel circuit PC may include eight transistors and one capacitor. Alternatively, the pixel circuit PC may include nine transistors and one capacitor, or the pixel circuit PC may include nine transistors and two capacitors. In an embodiment, for example, the pixel circuit PC may include two or more transistors and two or more capacitors.

Although not shown, the display apparatus 1 may include at least one of a first scan line, a second scan line, a third scan line, a fourth scan line, a data line, an emission control line, a power line, a first voltage line, a second voltage line, and a third voltage line electrically connected to the pixel circuit PC.

In an embodiment, the first to fourth scan lines may be configured to respectively transmit first to fourth scan signals to the pixel circuit PC, the data line may be configured to transmit a data voltage to the pixel circuit PC, the emission control line may be configured to transmit an emission control signal to the pixel circuit PC, the power line may be configured to transmit a first power voltage to the pixel circuit PC, and the first to third voltage lines may be configured to respectively transmit an initialization voltage, a reference voltage, and a bias voltage to the pixel circuit PC. However, the disclosure is not limited thereto.

In an embodiment, the first conductive layer 210 may extend in the first direction (the direction x). The first conductive layer 210 may be at least one of a first scan line, a second scan line, a third scan line, a fourth scan line, an emission control line, a power line, a first voltage line, a second voltage line, and a third voltage line. Accordingly, the first conductive layer 210 may transmit at least one of first to fourth scan signals, an emission control signal, a first power voltage, an initialization voltage, a reference voltage, and a bias voltage to the pixel circuit PC. Although FIG. 5 shows one first conductive layer 210, the disclosure is not limited thereto. The first conductive layer 210 may include a plurality of first conductive layers 210.

In an embodiment, the second conductive layer 220 may be arranged above the first conductive layer 210, such as further from the substrate 100 along a thickness direction than the first conductive layer 210. The second conductive layer 220 may at least partially overlap the first conductive layer 210 arranged below, such as to correspond to the first conductive layer 210 along the thickness direction. The second conductive layer 220 may extend in the second direction (the direction y) crossing the first direction (the direction x). The second conductive layer 220 may be at least one of a data line, a first voltage line, a second voltage line, and a third voltage line. Accordingly, the second conductive layer 220 may transmit at least one of a data voltage, a first power voltage, an initialization voltage, a reference voltage, and a bias voltage to the pixel circuit PC. Although FIG. 5 shows one second conductive layer 220, the disclosure is not limited thereto. The second conductive layer 220 may include a plurality of second conductive layers 220.

In an embodiment, the pixel electrode 310 may be arranged above the second conductive layer 220. The pixel electrode 310 may at least partially overlap the second conductive layer 220 arranged below. In addition, the pixel electrode 310 may at least partially overlap the pixel circuit PC. Although FIG. 5 shows a planar shape of the pixel electrode 310 being rectangular, the disclosure is not limited thereto. The pixel electrode 310 may have a polygonal shape, such as a triangle, a pentagon, or a hexagon, a circular shape, an oval shape, an irregular shape, or the like.

In an embodiment, the first conductive layer 210 may include a 1-1 conductive layer 210a (e.g., first conductive pattern) and a 1-2 conductive layer 210b (e.g., second conductive pattern). The 1-1 conductive layer 210a may be a portion of the first conductive layer 210 that at least partially overlaps the second conductive layer 220, and the 1-2 conductive layer 210b may be the rest of the first conductive layer 210 (e.g., remainder of the first conductive layer 210) that does not overlap the second conductive layer 220. However, the disclosure is not limited thereto. The 1-1 conductive layer 210a together with the 1-2 conductive layer 210b may define an entirety of the first conductive layer 210, without being limited thereto.

In an embodiment, the second conductive layer 220 may include a 2-1 conductive layer 220a (e.g., third conductive pattern) and a 2-2 conductive layer 220b (e.g., fourth conductive pattern). The 2-1 conductive layer 220a may be a portion of the second conductive layer 220 that at least partially overlaps the pixel electrode 310, and the 2-2 conductive layer 220b may be the rest of the second conductive layer 220 that does not overlap the pixel electrode 310. In addition, the 2-2 conductive layer 220b of the second conductive layer 220 may at least partially overlap the 1-1 conductive layer 210a of the first conductive layer 210.

FIG. 6 is a schematic cross-sectional enlarged view of the display apparatus 1 according to an embodiment. In more detail, FIG. 6 is a cross-sectional view of the display apparatus 1, taken along line I-I′ of FIG. 5.

Hereinafter, configurations included in the display apparatus 1 will be described in more detail according to a stacked structure with reference to FIG. 6.

Referring to FIG. 6, the substrate 100 may include a glass material, a ceramic material, a metal material, or a flexible or bendable material. When the substrate 100 is flexible or bendable, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate.

The substrate 100 may have a single-layer or multi-layer structure of the above-described material and may further include an inorganic layer in the case of a multi-layer structure. In some embodiments, the substrate 100 may have a structure of organic material/inorganic material/organic material/inorganic material.

A buffer layer 105 may be arranged on the substrate 100. The buffer layer 105 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOx). Zinc oxide (ZnOx) may be zinc oxide (ZnO) and/or zinc peroxide (ZnO₂). The buffer layer 105 may have a single-layer or multi-layer structure.

A first thin-film transistor TFT₁ and the capacitor Cst may be arranged on the buffer layer 105. The first thin-film transistor TFT₁ may include a first semiconductor layer A1, a first gate electrode G1, a first source electrode S1, and a first drain electrode D1. The capacitor Cst may include a first electrode CE1 and a second electrode CE2.

The first semiconductor layer A1 may be arranged on the buffer layer 105. The first semiconductor layer A1 may include amorphous silicon or may include polysilicon. The first semiconductor layer A1 may include a channel region, and a source region and a drain region arranged on both sides of the channel region. The source region and the drain region may be regions doped by adding a dopant. The first semiconductor layer A1 may include a single layer or multiple layers.

Although not shown, a lower metal layer may be between the substrate 100 and the buffer layer 105. The lower metal layer may include a conductive material including molybdenum (Mo), aluminum (Al), copper (Cu), titanium (Ti), etc. and may include multiple layers or a single layer including the above-described material.

The lower metal layer may at least partially overlap the first semiconductor layer A1. The lower metal layer may protect the first semiconductor layer A1. The lower metal layer may be configured such that an arbitrary (or preset) voltage is applied thereto. When a pixel circuit PC including both an n-channel MOSFET and a p-channel MOSFET is driven via the lower metal layer to which an arbitrary voltage is applied, unnecessary charges may be prevented from accumulating in the first semiconductor layer A1. As a result, characteristics of the first thin-film transistor TFT₁ including the first semiconductor layer A1 may be stably maintained.

A first insulating layer 111 and a second insulating layer 113 may be arranged above the substrate 100 to cover the first semiconductor layer A1. The first insulating layer 111 and the second insulating layer 113 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOx). Zinc oxide (ZnOx) may be zinc oxide (ZnO) and/or zinc peroxide (ZnO₂).

A first gate electrode G1 may be arranged on the first insulating layer 111. The first gate electrode G1 may include a conductive material including molybdenum (Mo), aluminum (Al), copper (Cu), titanium (Ti), etc. and may include multiple layers or a single layer including the above-described material. In addition, a first electrode CE1 may be arranged on the first insulating layer 111. In an embodiment, the first gate electrode G1 and the first electrode CE1 may be integrally provided with each other. However, the disclosure is not limited thereto. The first gate electrode G1 and the first electrode CE1 may be apart from each other as separate patterns.

The second electrode CE2 may be arranged on the second insulating layer 113. The second electrode CE2 may include a conductive material including molybdenum (Mo), aluminum (Al), copper (Cu), titanium (Ti), etc. and may include layers or a single layer including the above-described material.

The first electrode CE1 and the second electrode CE2 may overlap each other (e.g., face each other) with the second insulating layer 113 therebetween and may form electrical capacitance. In this case, the second insulating layer 113 may serve as a dielectric layer of the capacitor Cst.

An interlayer insulating layer 120 may be arranged on the second insulating layer 113 to cover the second electrode CE2. The interlayer insulating layer 120 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOx). Zinc oxide (ZnOx) may be zinc oxide (ZnO) and/or zinc peroxide (ZnO₂).

A first source electrode S1 and a first drain electrode D1 may be arranged on the interlayer insulating layer 120. The first source electrode S1 and the first drain electrode D1 may include a conductive material including molybdenum (Mo), aluminum (Al), copper (Cu), titanium (Ti), etc. and may include layers or a single layer including the above-described material. In an embodiment, for example, the first source electrode S1 and the first drain electrode D1 may have a multi-layer structure of Ti/Al/Ti. The first source electrode S1 and the first drain electrode D1 may be electrically connected to the source region and the drain region of a respective semiconductor layer arranged below, respectively, via contact holes in one or more insulating layers between the source/drain electrode layer and the respective semiconductor layer.

A first planarization layer 260 and a second planarization layer 270 may be arranged on the first source electrode S1 and the first drain electrode D1, and in order from the source/drain electrode layer. The first planarization layer 260 and the second planarization layer 270 may include, in a single layer or layers, a film including an organic material and may provide a flat upper surface. The first planarization layer 260 and the second planarization layer 270 may include a polymer such as benzocyclobutene (BCB), polyimide, hexamethyldisiloxane (HMDSO), polymethylmethacrylate (PMMA), or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

A connection electrode CM may be arranged on the first planarization layer 260. The connection electrode CM may include a conductive material including molybdenum (Mo), aluminum (Al), copper (Cu), titanium (Ti), etc. and may include layers or a single layer including the above-described material. The connection electrode CM may be electrically connected to the first source electrode S1 or the first drain electrode D1, via a contact hole defined in the first planarization layer 260.

The organic light-emitting diode OLED may be arranged on the second planarization layer 270. The organic light-emitting diode OLED may include the pixel electrode 310, an intermediate layer 320, and the opposite electrode 330.

The pixel electrode 310 may be arranged on the second planarization layer 270. The pixel electrode 310 may be a (semi)transmissive electrode or a reflective electrode. In an embodiment, the pixel electrode 310 may include a reflective layer including silver (Ag), magnesium (Mg), aluminum (Al), platinum (Pt), palladium (Pd), gold (Au), nickel (Ni), neodymium (Nd), iridium (Ir), chromium (Cr), and a compound thereof, and a transparent or semitransparent electrode layer on the reflective layer. In this regard, the transparent or semitransparent electrode layer may include at least one selected from indium tin oxide (ITO), indium zinc oxide (IZO), zinc oxide (ZnO), indium oxide (In₂O₃), indium gallium oxide (IGO), or aluminum zinc oxide (AZO). Alternatively, the pixel electrode 310 may have a structure of ITO/Ag/ITO.

The pixel electrode 310 may be electrically connected to the connection electrode CM, via a contact hole defined in the second planarization layer 270. As a result, the connection electrode CM may connect the pixel electrode 310 to the first thin-film transistor TFT1.

A pixel-defining layer 280 may be arranged on the second planarization layer 270. The pixel-defining layer 280 may prevent or reduce an (electrical) arc, etc. from occurring at an edge of the pixel electrode 310, by increasing a distance between the edge of the pixel electrode 310 and the opposite electrode 330 which is arranged above the pixel electrode 310.

The pixel-defining layer 280 may include one or more organic insulating materials selected from polyimide, polyamide, acrylic resin, BCB, and phenolic resin, and may be formed (or provided) by a method such as spin coating.

The intermediate layer 320 may be arranged in an opening OP defined in the pixel-defining layer 280. The intermediate layer 320 may include an emission layer. The emission layer may include an organic material including a fluorescent or phosphorescent material emitting red, green, blue, or white light. The emission layer may include a low-molecular weight organic material or a polymer organic material, and a functional layer such as a hole transport layer (HTL), a hole injection layer (NIL), an electron transport layer (ETL), or an electron injection layer (EIL) may be optionally further arranged under and on the emission layer.

The intermediate layer 320 may be arranged in correspondence with each of a plurality of pixel electrodes 310. However, the disclosure is not limited thereto. Various modifications may be made, for example, the intermediate layer 320 may include one layer over the plurality of pixel electrodes 310.

The opposite electrode 330 may be a transmissive electrode or a reflective electrode. Alternatively, in an embodiment, the opposite electrode 330 may be a transparent or semitransparent electrode and may include a metal thin film having a low work function including Li, Ca, LiF/Ca, LiF/Al, Al, Ag, Mg, and a compound thereof. In addition, a transparent conductive oxide (TCO) film such as ITO, IZO, ZnO, or In₂O₃ may be further arranged on the metal thin film. The opposite electrode 330 may be arranged in the display area DA, and may be arranged on the intermediate layer 320 and extend from the opening OP, and along a sidewall and a top surface of the pixel-defining layer 280. The opposite electrode 330 may be integrally formed in a plurality of organic light-emitting diodes OLED to correspond to the plurality of pixel electrodes 310.

The organic light-emitting diode OLED may be covered by an encapsulation layer (not shown). The encapsulation layer may include at least one organic layer and at least one inorganic layer. The at least one inorganic layer may include one or more inorganic materials from among aluminum oxide, titanium oxide, tantalum oxide, hafnium oxide, zinc oxide, silicon oxide, silicon nitride, and silicon oxynitride. The at least one inorganic layer may include a single layer or layers including the above-described material. The at least one organic layer may include a polymer-based material. Examples of the polymer-based material may include an acryl-based resin such as PMMA or polyacrylic acid, an epoxy-based resin, polyimide, and polyethylene. In an embodiment, the at least one organic layer may include acrylate polymer.

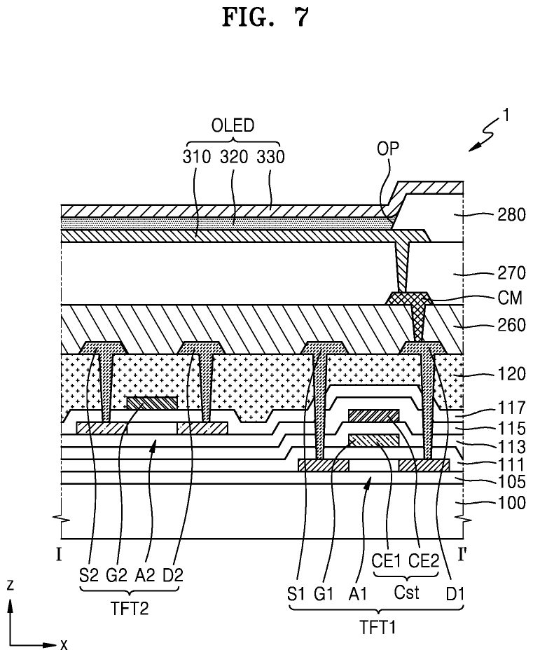

FIG. 7 is a schematic cross-sectional enlarged view of the display apparatus 1 according to an embodiment. The embodiment of FIG. 7 is different from that of FIG. 6 in that the display apparatus 1 further includes a second semiconductor layer A2 including a different material from that of the first semiconductor layer A1. The second semiconductor layer A2 may be in a different layer than the first semiconductor layer A1. In FIG. 7, the same reference numerals as those in FIG. 6 denote the same elements, and thus, redundant descriptions thereof are omitted.

Referring to FIG. 7, the buffer layer 105, the first insulating layer 111, the second insulating layer 113, a third insulating layer 115, and a fourth insulating layer 117 may be sequentially arranged on the substrate 100 (e.g., in order in a direction away from the substrate 100). In addition, the first thin-film transistor TFT1 and a second thin-film transistor TFT2 may be arranged above the substrate 100. The first thin-film transistor TFT1 may include the first semiconductor layer A1, the first gate electrode G1, the first source electrode S1, and the first drain electrode D1. The second thin-film transistor TFT2 may include a second semiconductor layer A2, a second gate electrode G2, a second source electrode S2, and a second drain electrode D2.

The first semiconductor layer A1 may be arranged on the buffer layer 105, and the second semiconductor layer A2 may be arranged on the third insulating layer 115. The first semiconductor layer A1 and the second semiconductor layer A2 may include different materials from each other. In an embodiment, for example, the first semiconductor layer A1 may include a silicon semiconductor material, and the second semiconductor layer A2 may include an oxide semiconductor material.

The second semiconductor layer A2 may include oxide of at least one material selected from indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce) and zinc (Zn). In an embodiment, for example, the second semiconductor layer A2 may be an InSnZnO (ITZO) semiconductor layer, an InGaZnO (IGZO) semiconductor layer, etc. Since an oxide semiconductor has a wide band gap (about 3.1 electron volts (eV)), a high carrier mobility, and a low leakage current, a voltage drop thereof is not great even when a driving period is relatively long, and thus, a change in brightness due to a voltage drop is not great even during low-frequency driving.

The second semiconductor layer A2 may include a channel region, and a source region and a drain region arranged on both sides of the channel region. The second semiconductor layer A2 may include a single layer or multiple layers.

Although not shown, a light-blocking electrode may be arranged under the second semiconductor layer A2. Since the second semiconductor layer A2 including an oxide semiconductor material is vulnerable to light, the second semiconductor layer A2 may be protected via the light-blocking electrode. In more detail, the light-blocking electrode may prevent or reduce device characteristics of the second thin-film transistor TFT2 including an oxide semiconductor material from being changed by a photocurrent of the second semiconductor layer A2 induced by external light incident from the substrate 100 side.

The fourth insulating layer 117 may be arranged on the second semiconductor layer A2, and the second gate electrode G2 may be arranged on the fourth insulating layer 117. Although FIG. 7 shows the fourth insulating layer 117 being arranged over the entire surface of the substrate 100 to cover the second semiconductor layer A2, the disclosure is not limited thereto. In an embodiment, for example, the fourth insulating layer 117 may be patterned to overlap a channel region of the second semiconductor layer A2.

The interlayer insulating layer 120 may be arranged on the second gate electrode G2, and the first source electrode S1, the first drain electrode D1, the second source electrode S2 and the second drain electrode D2 may be arranged on the interlayer insulating layer 120. The first source electrode S1 and the first drain electrode D1 may be electrically connected to a source region and a drain region of the first semiconductor layer A1 arranged below via contact holes, respectively. In addition, the second source electrode S2 and the second drain electrode D2 may be electrically connected to a source region and a drain region of the second semiconductor layer A2 arranged below via contact holes, respectively.

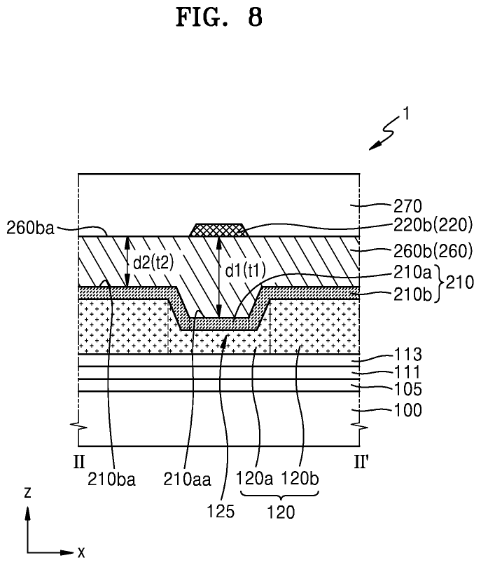

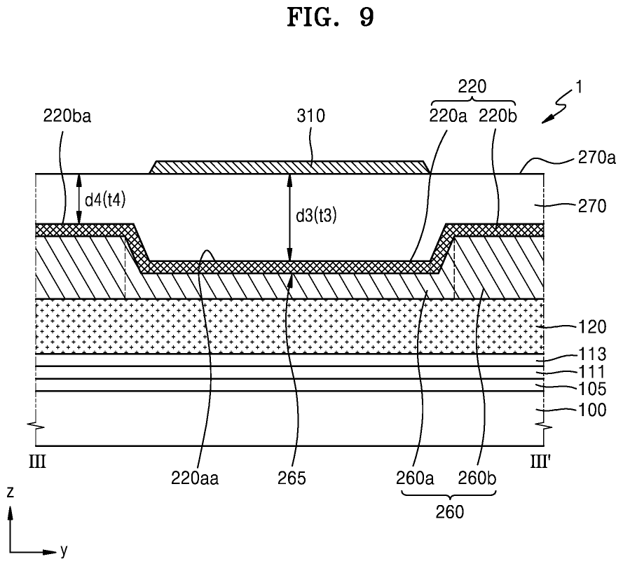

FIGS. 8 and 9 are schematic cross-sectional views of the display apparatus 1 according to an embodiment. In more detail, FIG. 8 is a cross-sectional view of the display apparatus 1, taken along line II-II′ of FIG. 5, and FIG. 9 is a cross-sectional view of the display apparatus 1, taken along line III-III′ of FIG. 5.

Referring to FIGS. 5, 8, and 9, the display apparatus 1 may include the substrate 100, the first conductive layer 210, the first planarization layer 260, the second conductive layer 220, the second planarization layer 270, and the pixel electrode 310.

The buffer layer 105, the first insulating layer 111, and the second insulating layer 113 may be sequentially arranged on the substrate 100. Although not shown, an electrode or a wire may be arranged between the first insulating layer 111 and the second insulating layer 113.

In an embodiment, the interlayer insulating layer 120 may be arranged on the second insulating layer 113. The interlayer insulating layer 120 may include a first portion 120a corresponding to the second conductive layer 220 and defining a first groove 125, and a second portion 120b which is extended from and adjacent to the first portion 120a. The first portion 120a and the second portion 120b of the interlayer insulating layer 120 may be integrally provided with each other. A portion of the interlayer insulating layer 120 in which the first groove 125 is formed may correspond to the first portion 120a, and a portion of the interlayer insulating layer 120 minus the first portion 120a (e.g., a remaining portion) may correspond to the second portion 120b. However, the disclosure is not limited thereto.

In an embodiment, the first conductive layer 210 may be arranged on the interlayer insulating layer 120. The first conductive layer 210 may include the same material as that of the first source electrode S1 and/or the first drain electrode D1 described above with reference to FIG. 6. As including a same material elements may be on a same layer, in a same layer as each other as respective portions of a same material layer, may form an interface with a same underlying or overlying layer, etc., without being limited thereto.

The first conductive layer 210 may include a 1-1 conductive layer 210a arranged in the first groove 125 formed in (or by) the first portion 120a of the interlayer insulating layer 120, and a 1-2 conductive layer 210b which is extended from the 1-1 conductive layer 210a and along the second portion 120b of the interlayer insulating layer 120. At least a portion of the 1-2 conductive layer 210b may be arranged on the first portion 120a of the interlayer insulating layer 120. The 1-1 conductive layer 210a and the 1-2 conductive layer 210b may be integrally provided with each other.

In an embodiment, the first planarization layer 260 may be arranged on the first conductive layer 210 and/or the interlayer insulating layer 120. The first planarization layer 260 may include a third portion 260a corresponding to the pixel electrode 310 and defining a second groove 265, and a fourth portion 260b which is adjacent to the third portion 260a and extended therefrom. The third portion 260a and the fourth portion 260b of the first planarization layer 260 may be integrally provided with each other. A portion of the first planarization layer 260 in which the second groove 265 is formed may correspond to the third portion 260a, and a portion of the first planarization layer 260 minus the third portion 260a may correspond to the fourth portion 260b. However, the disclosure is not limited thereto.

In an embodiment, the second conductive layer 220 may be arranged on the first planarization layer 260. The second conductive layer 220 may include the same material as that of the connection electrode CM described above with reference to FIG. 6.

The second conductive layer 220 may include a 2-1 conductive layer 220a arranged in the second groove 265 formed in (or by) the third portion 260a of the first planarization layer 260, and a 2-2 conductive layer 220b which is extended from the 2-1 conductive layer 220a and arranged on the fourth portion 260b of the first planarization layer 260. At least a portion of the 2-2 conductive layer 220b may be arranged on the third portion 260a of the first planarization layer 260. The 2-1 conductive layer 220a and the 2-2 conductive layer 220b may be integrally provided with each other.

In an embodiment, the second planarization layer 270 may be arranged on the second conductive layer 220, and the pixel electrode 310 may be arranged on the second planarization layer 270.

The number of transistors and capacitors included in a pixel circuit PC may be increased to implement a display apparatus 1 of high resolution and high speed. As a result, wires (e.g., conductive patterns) may overlap each other in a direction vertical (or normal) to the substrate 100 (the direction z), and a distance between the wires overlapping each other along the thickness direction (the direction z) may be decreased.

When the first conductive layer 210 and the second conductive layer 220 overlap each other at an overlapping area, and a distance between the first conductive layer 210 and the second conductive layer 220 is close, parasitic capacitance is formed between the first conductive layer 210 and the second conductive layer 220. As a result of the parasitic capacitance, RC-delay increases, which may cause crosstalk or stains on a display panel. In more detail, assuming that the first conductive layer 210 is a scan line SL and the second conductive layer 220 is a data line DL, parasitic capacitance is formed between the first conductive layer 210 and the second conductive layer 220. Thus, a load (e.g., electrical load) of the second conductive layer 220 increases, which may increase RC-delay. In addition, when RC-delay of the second conductive layer 220 increases, data charging time is insufficient, which may cause crosstalk or stains on a display panel.

In an embodiment, in a direction vertical to the substrate 100 (the direction z), the second conductive layer 220 may at least partially overlap the first conductive layer 210 arranged below and closer to the substrate 100. In more detail, in a direction vertical to the substrate 100 (the direction z), the 2-2 conductive layer 220b of the second conductive layer 220 may overlap (or at least partially overlap) the 1-1 conductive layer 210a of the first conductive layer 210, at a first overlapping area. In addition, the 1-2 conductive layer 210b of the first conductive layer 210 may not overlap the second conductive layer 220. However, the disclosure is not limited thereto.

Since the first groove 125 is formed in the interlayer insulating layer 120, and the 1-1 conductive layer 210a of the first conductive layer 210 is arranged in the first groove 125, a first distance d1 from an upper surface 210aa of the 1-1 conductive layer 210a, to an upper surface 260ba of the first planarization layer 260, may be greater than a second distance d2 from an upper surface 210ba of the 1-2 conductive layer 210b, to the upper surface 260ba of the first planarization layer 260, in a direction vertical to the substrate 100 (the direction z). A respective upper surface may be furthest from the substrate 100.

In addition, since the first groove 125 is formed in the interlayer insulating layer 120, and the 1-1 conductive layer 210a of the first conductive layer 210 is arranged in the first groove 125, a first thickness t1 of the first planarization layer 260 at the 1-1 conductive layer 210a may be greater than a second thickness t2 of the first planarization layer 260 at the 1-2 conductive layer 210b.

Since the first groove 125 is formed in the interlayer insulating layer 120, and the 1-1 conductive layer 210a of the first conductive layer 210 is arranged in the first groove 125, a distance between the 1-1 conductive layer 210a and the 2-2 conductive layer 220b may be increased. Since a distance between the 1-1 conductive layer 210a and the 2-2 conductive layer 220b is increased, parasitic capacitance may be prevented or reduced from being formed between the 1-1 conductive layer 210a and the 2-2 conductive layer 220b, and RC-delay may be prevented or reduced from increasing.

In other words, a distance between the 1-1 conductive layer 210a and the 2-2 conductive layer 220b is increased by forming the first groove 125 in the interlayer insulating layer 120 at a first overlapping area where the 2-2 conductive layer 220b of the second conductive layer 220 and the 1-1 conductive layer 210a of the first conductive layer 210 overlap each other. Thus, parasitic capacitance may be prevented or reduced from being formed between the 1-1 conductive layer 210a and the 2-2 conductive layer 220b, and RC-delay may be prevented or reduced from increasing.

In addition, when the second conductive layer 220 and the pixel electrode 310 overlap each other at an overlapping area, and a distance between the second conductive layer 220 and the pixel electrode 310 is close, parasitic capacitance is formed between the second conductive layer 220 and the pixel electrode 310. As a result, RC-delay increases, which may cause crosstalk or stains on a display panel. In more detail, assuming that the second conductive layer 220 is a data line DL, parasitic capacitance is formed between the second conductive layer 220 and the pixel electrode 310, and thus, a load of the second conductive layer 220 increases, which may increase RC-delay. In addition, when RC-delay of the second conductive layer 220 increases, data charging time is insufficient, which may cause crosstalk or stains on a display panel.

In an embodiment, in a direction vertical to the substrate 100 (the direction z), the pixel electrode 310 may at least partially overlap the second conductive layer 220 arranged below, to define a second overlapping area. In more detail, in a direction vertical to the substrate 100 (the direction z), the pixel electrode 310 may overlap (or at least partially overlap) the 2-1 conductive layer 220a of the second conductive layer 220. In addition, the pixel electrode 310 may not overlap the 2-2 conductive layer 220b of the second conductive layer 220. However, the disclosure is not limited thereto.

Since the second groove 265 is formed in the first planarization layer 260, and the 2-1 conductive layer 220a of the second conductive layer 220 is arranged in the second groove 265, a third distance d3 from an upper surface 220aa of the 2-1 conductive layer 220a to an upper surface 270a of the second planarization layer 270, may be greater than a fourth distance d4 from an upper surface 220ba of the 2-2 conductive layer 220b to the upper surface 270a of the second planarization layer 270 in a direction vertical to the substrate 100 (the direction z).

In addition, since the second groove 265 is formed in the first planarization layer 260, and the 2-1 conductive layer 220a of the second conductive layer 220 is arranged in the second groove 265, a third thickness t3 of the second planarization layer 270 at the 2-1 conductive layer 220a may be greater than a fourth thickness t4 of the second planarization layer 270 at the 2-2 conductive layer 220b.

Since the second groove 265 is formed in the first planarization layer 260, and the 2-1 conductive layer 220a of the second conductive layer 220 is arranged in the second groove 265, a distance between the 2-1 conductive layer 220a and the pixel electrode 310 may be increased. Since a distance between the 2-1 conductive layer 220a and the pixel electrode 310 is increased, parasitic capacitance may be prevented or reduced from being formed between the 2-1 conductive layer 220a and the pixel electrode 310, and RC-delay may be prevented or reduced from increasing.

In other words, a distance between the 2-1 conductive layer 220a and the pixel electrode 310 is increased by forming the second groove 265 in the first planarization layer 260 at an overlapping area where the pixel electrode 310 and the 2-1 conductive layer 220a of the second conductive layer 220 overlap each other. Thus, parasitic capacitance may be prevented or reduced from being formed between the 2-1 conductive layer 220a and the pixel electrode 310, and RC-delay may be prevented or reduced from increasing.

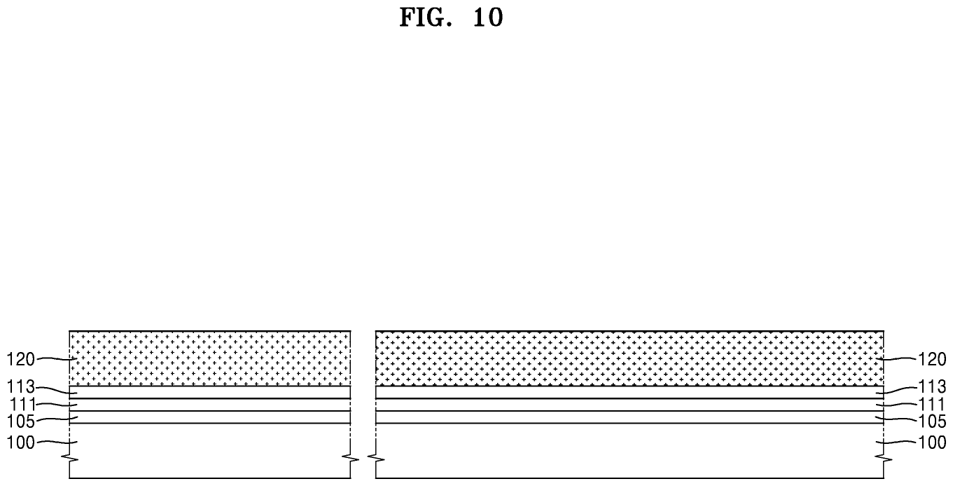

FIGS. 10 to 22 are schematic cross-sectional views of processes in a method of providing (or manufacturing) a display apparatus 1, according to an embodiment.

Hereinafter, a method of manufacturing a display apparatus 1 will be described with reference to FIGS. 10 to 22.

Referring to FIGS. 10 to 22, a method of providing (or manufacturing) a display apparatus 1, according to an embodiment, may include an operation of forming the interlayer insulating layer 120 above the substrate 100, an operation of forming the first groove 125 in the interlayer insulating layer 120, an operation of forming the first conductive layer 210 on the interlayer insulating layer 120, the first conductive layer 210 including the 1-1 conductive layer 210a and the 1-2 conductive layer 210b, an operation of forming the first planarization layer 260 on the first conductive layer 210, an operation of forming the second groove 265 in the first planarization layer 260, and an operation of forming the second conductive layer 220 on the first planarization layer 260, the second conductive layer 220 including the 2-1 conductive layer 220a and the 2-2 conductive layer 220b.

In addition, the operation of forming the first groove 125 in the interlayer insulating layer 120 may include an operation of forming a photoresist pattern PR on the interlayer insulating layer 120, an operation of exposing the photoresist pattern PR to light by using a first halftone mask 500, an operation of developing the photoresist pattern PR exposed to light, an operation of etching the interlayer insulating layer 120, and an operation of removing the photoresist pattern PR.

In addition, the operation of forming the second groove 265 in the first planarization layer 260 may include an operation of exposing the first planarization layer 260 to light by using a second halftone mask 600 and an operation of developing the first planarization layer 260 exposed to light to form the second groove 265.

Referring to FIG. 10, the interlayer insulating layer 120 may be formed above the substrate 100. Before the interlayer insulating layer 120 is formed above the substrate 100, the buffer layer 105, the first insulating layer 111, and the second insulating layer 113 may be formed on the substrate 100. The first insulating layer 111, the second insulating layer 113 and the interlayer insulating layer 120 may together form or be referred to as an insulating layer.

In addition, before the interlayer insulating layer 120 is formed above the substrate 100, the first thin-film transistor TFT1 (refer to FIG. 6) described above with reference to FIG. 6 may be formed above the substrate 100. In more detail, before the interlayer insulating layer 120 is formed above the substrate 100, the first semiconductor layer A1 (refer to FIG. 6), the first gate electrode G1 (refer to FIG. 6), and the second electrode CE2 (refer to FIG. 6) may be formed above the substrate 100. In this regard, the first semiconductor layer A1 may be formed on the buffer layer 105, the first gate electrode G1 may be formed on the first insulating layer 111, and the second electrode CE2 may be formed on the second insulating layer 113.

In addition, when a display apparatus 1 includes the second semiconductor layer A2 (refer to FIG. 7) including a different material from that of the first semiconductor layer A1, the third insulating layer 115 and the fourth insulating layer 117 may be additionally formed above the substrate 100. In this regard, the second semiconductor layer A2 may be formed on the third insulating layer 115, and the second gate electrode G2 may be formed on the fourth insulating layer 117.

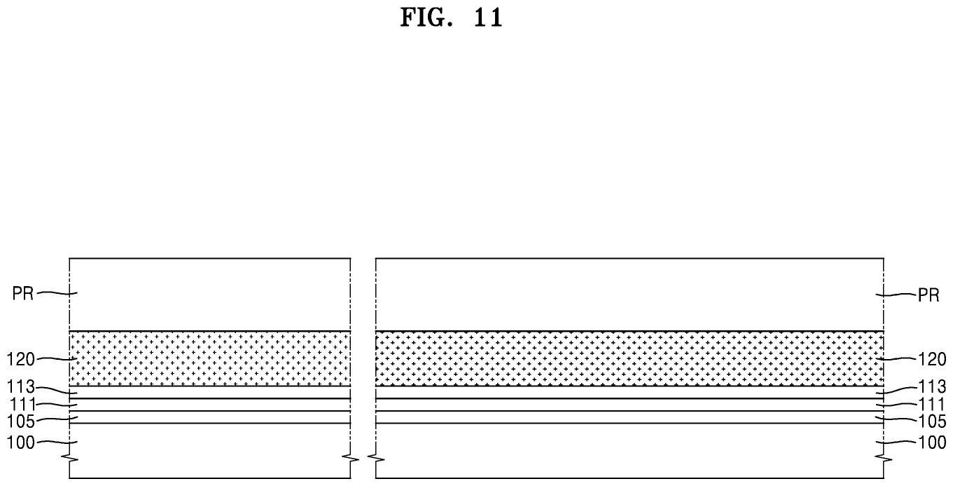

Referring to FIG. 11, after the operation of forming the interlayer insulating layer 120 on the insulating layer and above the substrate 100, the operation of forming the photoresist pattern PR on the interlayer insulating layer 120 may be performed. Although the photoresist pattern PR is described in the present specification as being of a positive type, the disclosure is not limited thereto. The photoresist pattern PR may be of a negative type.

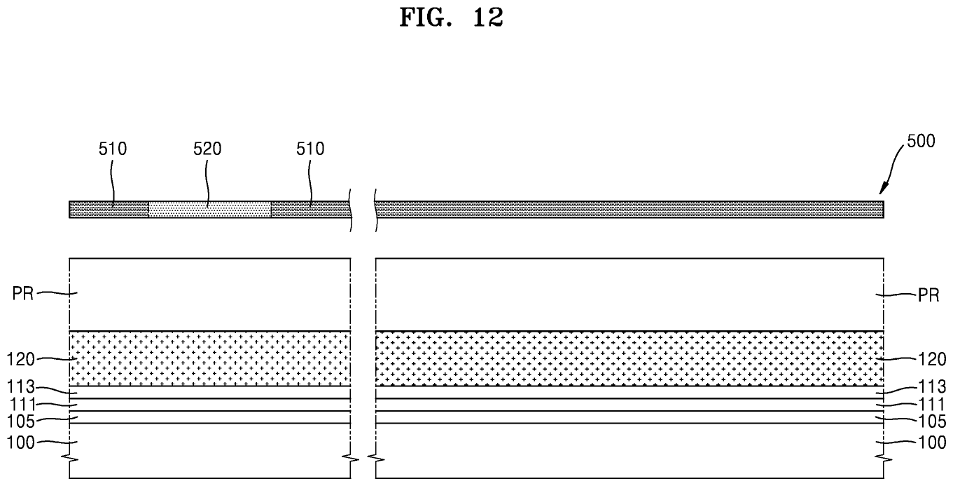

Referring to FIG. 12, after the operation of forming the photoresist pattern PR on the interlayer insulating layer 120, the operation of exposing the photoresist pattern PR to light by using the first halftone mask 500 may be performed. In an embodiment, a portion of the photoresist pattern PR may be exposed to light by using the first halftone mask 500 including a blocking area 510 and a semi-transmissive area 520. In this regard, light is not transmitted through the blocking area 510 of the first halftone mask 500, and about 50% of light may be transmitted through the semi-transmissive area 520 of the first halftone mask 500. However, the disclosure is not limited thereto. In addition, although not shown, the first halftone mask 500 may further include a transmissive area, and light may be transmitted through the transmissive area.

Accordingly, since light is partially transmitted through the semi-transmissive area 520 of the first halftone mask 500, a portion of the photoresist pattern PR corresponding to the semi-transmissive area 520 may be partially exposed to light, and a portion of the photoresist pattern PR corresponding to the blocking area 510 may not be exposed to light.

Although not shown, a wire formed above the interlayer insulating layer 120 and a wire arranged under the interlayer insulating layer 120 may be electrically connected to each other via a contact hole defined in the interlayer insulating layer 120. Accordingly, after the interlayer insulating layer 120 is formed, a process of forming a contact hole in the interlayer insulating layer 120 may be performed. According to one or more embodiments, the first groove 125 may be formed in the interlayer insulating layer 120 at the same time during a process of forming a contact hole in the interlayer insulating layer 120 without adding a separate mask, such as by using a same halftone mask.

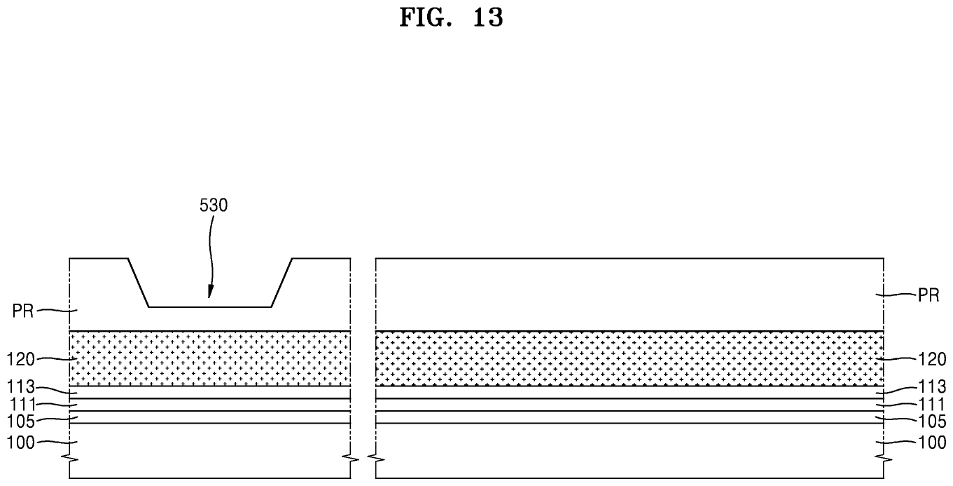

Referring to FIG. 13, after the operation of exposing the photoresist pattern PR to light by using the first halftone mask 500, the operation of developing the photoresist pattern PR exposed to light may be performed. A portion of the photoresist pattern PR corresponding to the semi-transmissive area 520 of the first halftone mask 500 may be partially exposed to light, and a portion of the photoresist pattern PR exposed to light may be developed during the operation of developing the photoresist pattern PR. In this regard, a portion of the photoresist pattern PR may have an exposed portion developed, and thus, a groove 530 may be formed in the photoresist pattern PR.

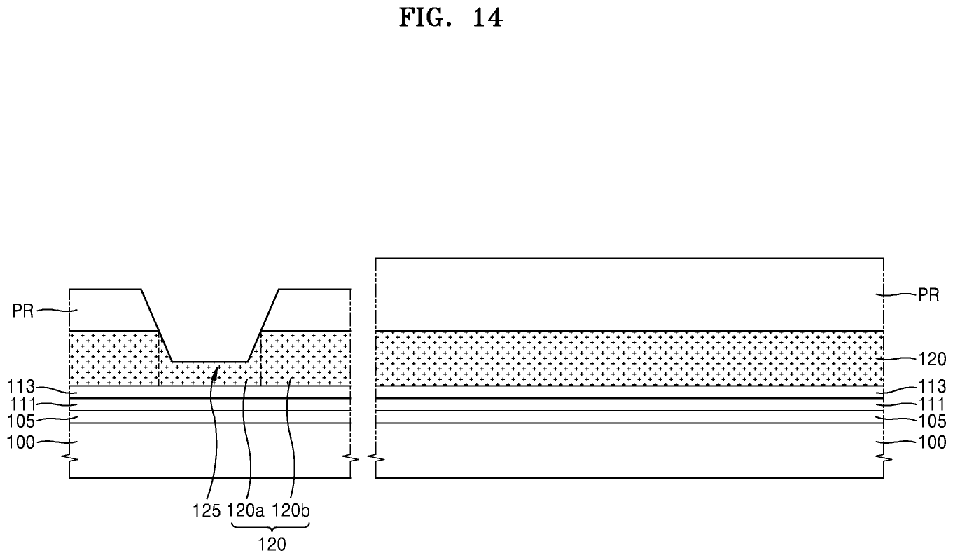

Referring to FIG. 14, after the operation of developing the photoresist pattern PR exposed to light, the operation of etching the interlayer insulating layer 120 may be performed. In more detail, the first groove 125 may be formed in the interlayer insulating layer 120 by etching the photoresist pattern PR and the interlayer insulating layer 120. The first groove 125 of the interlayer insulating layer 120 may be formed at a position corresponding to a portion in which the groove 530 of the photoresist pattern PR is formed. The first groove 125 of the interlayer insulating layer 120 may be provided at a position corresponding to an overlapping area of two signal lines.

In an embodiment, the interlayer insulating layer 120 may include the first portion 120a at which the first groove 125 is formed, and the second portion 120b adjacent to the first portion 120a. The first portion 120a and the second portion 120b of the interlayer insulating layer 120 may be integrally provided with each other. A portion of the interlayer insulating layer 120 at which the first groove 125 is formed may correspond to the first portion 120a and include a sidewall and a top surface of the interlayer insulating layer 120 which define the first groove 125, and a portion of the interlayer insulating layer 120 minus the first portion 120a (e.g., a remaining portion) may correspond to the second portion 120b. However, the disclosure is not limited thereto.

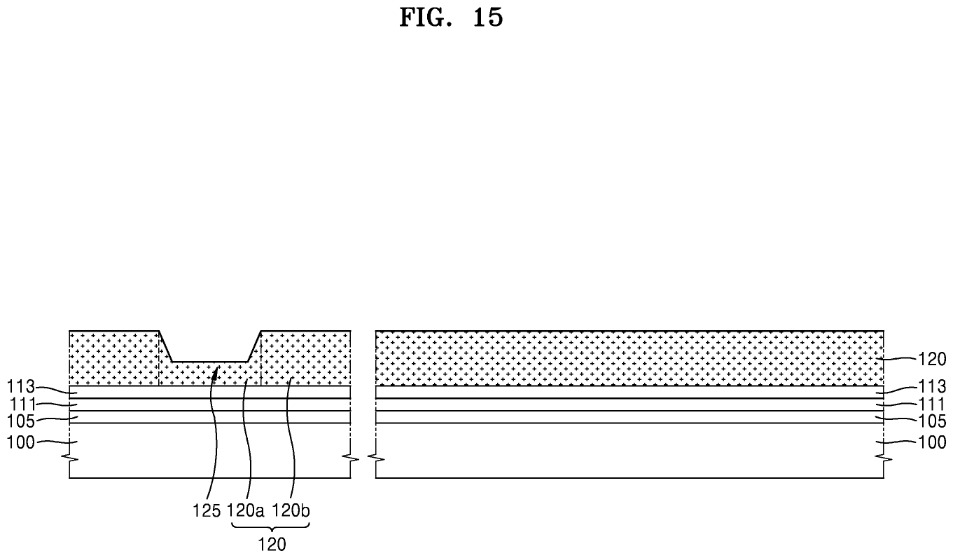

Referring to FIG. 15, after the operation of etching the interlayer insulating layer 120, the operation of removing the photoresist pattern PR may be performed. The operation of removing the photoresist pattern PR may be an operation of stripping photoresist patterns PR left after etching the interlayer insulating layer 120. The removal of the photoresist pattern PR exposes a top surface of the interlayer insulating layer 120, at both the first portion 120a and the second portion 120b thereof.

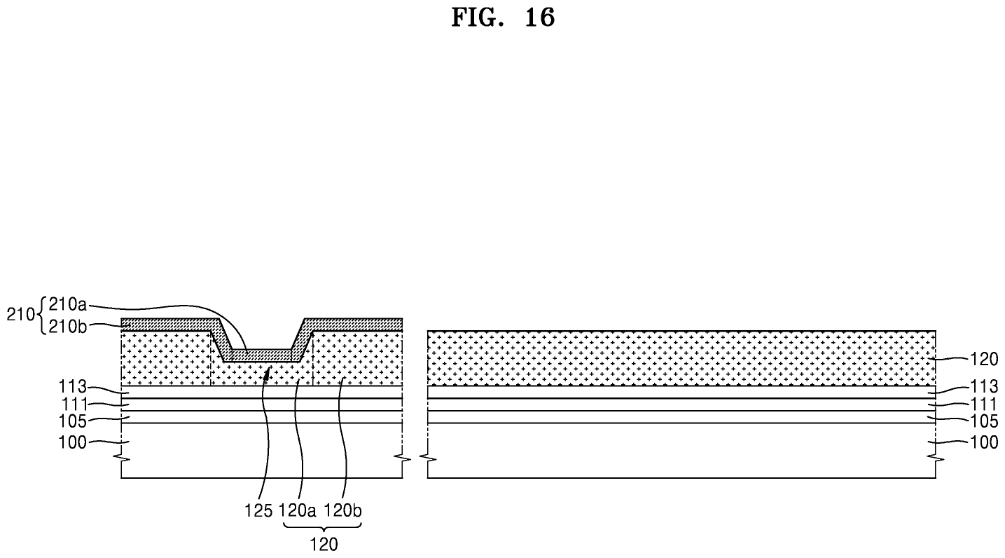

Referring to FIG. 16, after the operation of removing the photoresist pattern PR, the operation of forming the first conductive layer 210 on the interlayer insulating layer 120, the first conductive layer 210 including the 1-1 conductive layer 210a (e.g., first conductive pattern) and the 1-2 conductive layer 210b (e.g., second conductive pattern), may be performed.

The interlayer insulating layer 120 may include the first portion 120a and the second portion 120b, and the first conductive layer 210 may include the 1-1 conductive layer 210a and the 1-2 conductive layer 210b. The 1-1 conductive layer 210a and the 1-2 conductive layer 210b may be integrally provided with each other. However, the disclosure is not limited thereto.

The first conductive layer 210 may be formed on the interlayer insulating layer 120. In more detail, the 1-1 conductive layer 210a of the first conductive layer 210 may be formed on the first portion 120a of the interlayer insulating layer 120, and the 1-2 conductive layer 210b of the first conductive layer 210 may be formed on the second portion 120b of the interlayer insulating layer 120. However, at least a portion of the 1-2 conductive layer 210b of the first conductive layer 210 may be formed even on the first portion 120a of the interlayer insulating layer 120. In this regard, the first groove 125 is formed in the first portion 120a of the interlayer insulating layer 120, and accordingly, the 1-1 conductive layer 210a of the first conductive layer 210 may be formed in the first groove 125. The first conductive layer 210 in the first groove 125 extends along the top surface of the first portion 120a of the interlayer insulating layer 120, along the sidewall of the interlayer insulating layer 120, out of the first groove 125, and along the top surface of the second portion 120b of the interlayer insulating layer 120 in a direction away from the first groove 125.

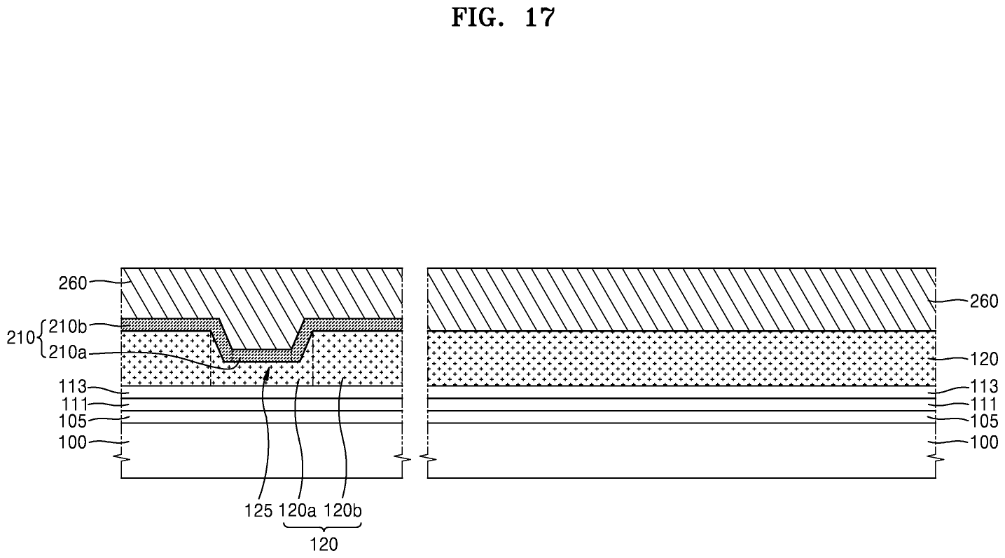

Referring to FIG. 17, after the operation of forming the first conductive layer 210 on the interlayer insulating layer 120, the operation of forming the first planarization layer 260 on the first conductive layer 210 may be performed. The first planarization layer 260 may cover an entirety of the first conductive layer 210 and/or the interlayer insulating layer 120.

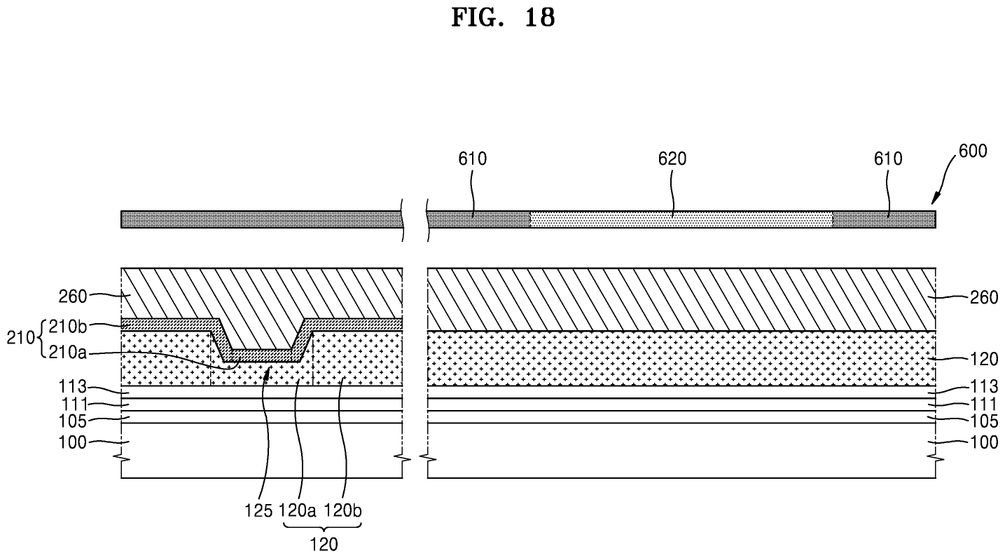

Referring to FIG. 18, after the operation of forming the first planarization layer 260 on the first conductive layer 210, the operation of exposing the first planarization layer 260 to light by using the second halftone mask 600 may be performed. In an embodiment, a portion of the first planarization layer 260 may be exposed to light by using the second halftone mask 600 including a blocking area 610 and a semi-transmissive area 620. In this regard, light is not transmitted through the blocking area 610 of the second halftone mask 600, and about 50% of light may be transmitted through the semi-transmissive area 620 of the second halftone mask 600. However, the disclosure is not limited thereto. In addition, although not shown, the second halftone mask 600 may further include a transmissive area, and light may be transmitted through the transmissive area.

Accordingly, since light is partially transmitted through the semi-transmissive area 620 of the second halftone mask 600, a portion of the first planarization layer 260 corresponding to the semi-transmissive area 620 may be partially exposed to light, and a portion of the first planarization layer 260 corresponding to the blocking area 610 may not be exposed to light.

Although not shown, a wire formed above the first planarization layer 260 and a wire arranged under the first planarization layer 260 may be electrically connected to each other via a contact hole defined in the first planarization layer 260. Accordingly, after the first planarization layer 260 is formed, a process of forming a contact hole in the first planarization layer 260 may be performed. According to one or more embodiments, the second groove 265 may be formed in the first planarization layer 260 at the same time during a process of forming a contact hole in the first planarization layer 260 without adding a separate mask, by using a same halftone mask.

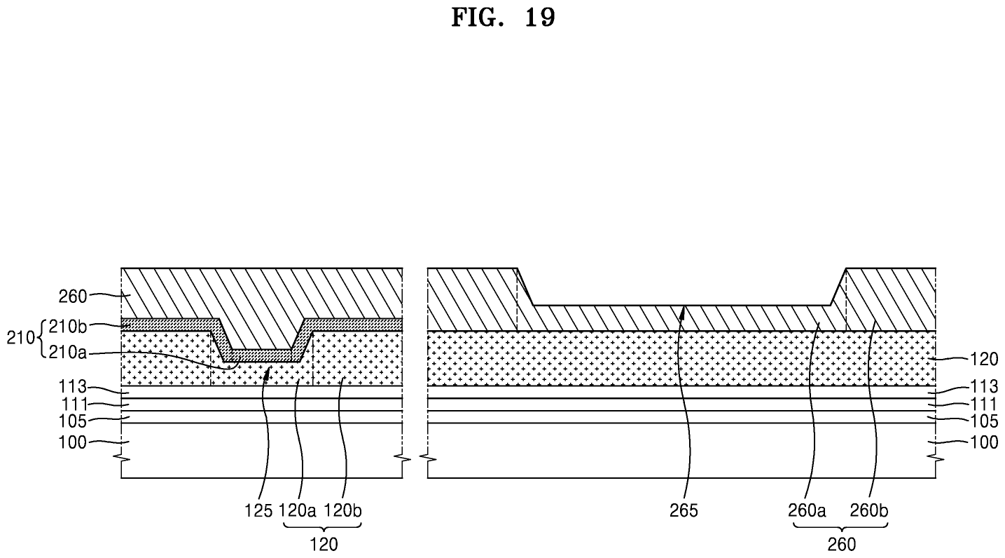

Referring to FIG. 19, after the operation of exposing the first planarization layer 260 to light by using the second halftone mask 600, the operation of developing the first planarization layer 260 exposed to light may be performed. A portion of the first planarization layer 260 corresponding to the semi-transmissive area 620 of the second halftone mask 600 may be partially exposed to light, and a portion of the first planarization layer 260 exposed to light may be developed during the operation of developing the first planarization layer 260. In this regard, a portion of the first planarization layer 260 may have an exposed portion developed, and thus, the second groove 265 may be formed.

In an embodiment, the first planarization layer 260 may include the third portion 260a which defines the second groove 265, and the fourth portion 260b adjacent to the third portion 260a. The third portion 260a and the fourth portion 260b of the first planarization layer 260 may be integrally provided with each other. A portion of the first planarization layer 260 which defines the second groove 265 may correspond to the third portion 260a and include a sidewall and a top surface of the first planarization layer 260 which define the second groove 265, and a portion of the first planarization layer 260 minus the third portion 260a may correspond to the fourth portion 260b. However, the disclosure is not limited thereto.

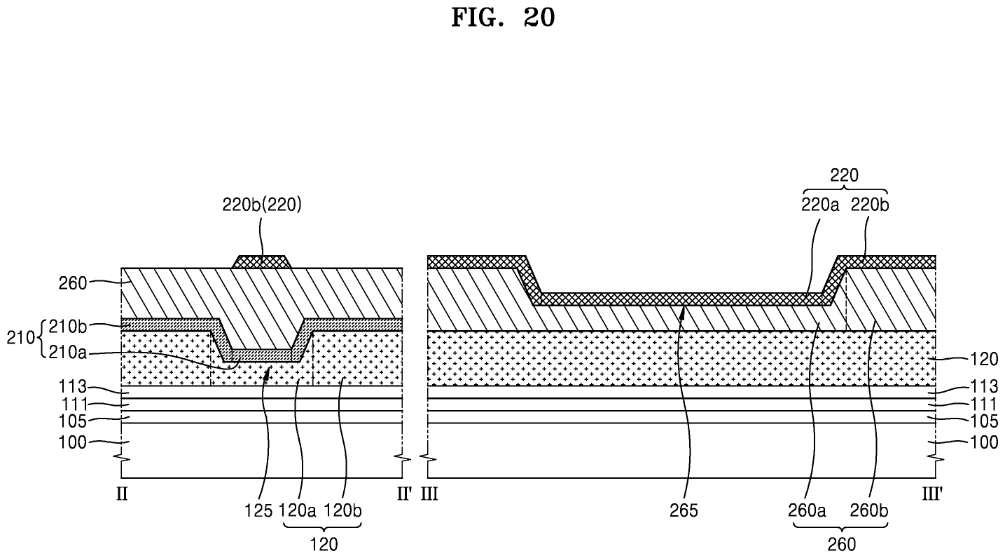

Referring to FIG. 20, after the operation of developing the first planarization layer 260 exposed to light, the operation of forming the second conductive layer 220 on the first planarization layer 260, the second conductive layer 220 including the 2-1 conductive layer 220a (e.g., third conductive pattern) and the 2-2 conductive layer 220b (e.g., fourth conductive pattern), may be performed.

The first planarization layer 260 may include the third portion 260a and the fourth portion 260b, and the second conductive layer 220 may include the 2-1 conductive layer 220a and the 2-2 conductive layer 220b. The 2-1 conductive layer 220a and the 2-2 conductive layer 220b may be integrally provided with each other. However, the disclosure is not limited thereto.

The second conductive layer 220 may be formed on the first planarization layer 260. In more detail, the 2-1 conductive layer 220a of the second conductive layer 220 may be formed on the third portion 260a of the first planarization layer 260, and the 2-2 conductive layer 220b of the second conductive layer 220 may be formed on the fourth portion 260b of the first planarization layer 260. However, at least a portion of the 2-2 conductive layer 220b of the second conductive layer 220 may be formed even on the third portion 260a of the first planarization layer 260. In this regard, the second groove 265 is formed in the third portion 260a of the first planarization layer 260, and accordingly, the 2-1 conductive layer 220a of the second conductive layer 220 may be formed in the second groove 265. The second conductive layer 220 in the second groove 265 extends along the top surface of the third portion 260a of the first planarization layer 260, along the sidewall of the first planarization layer 260, out of the second groove 265, and along the top surface of the fourth portion 260b of the first planarization layer 260 in a direction away from the second groove 265.

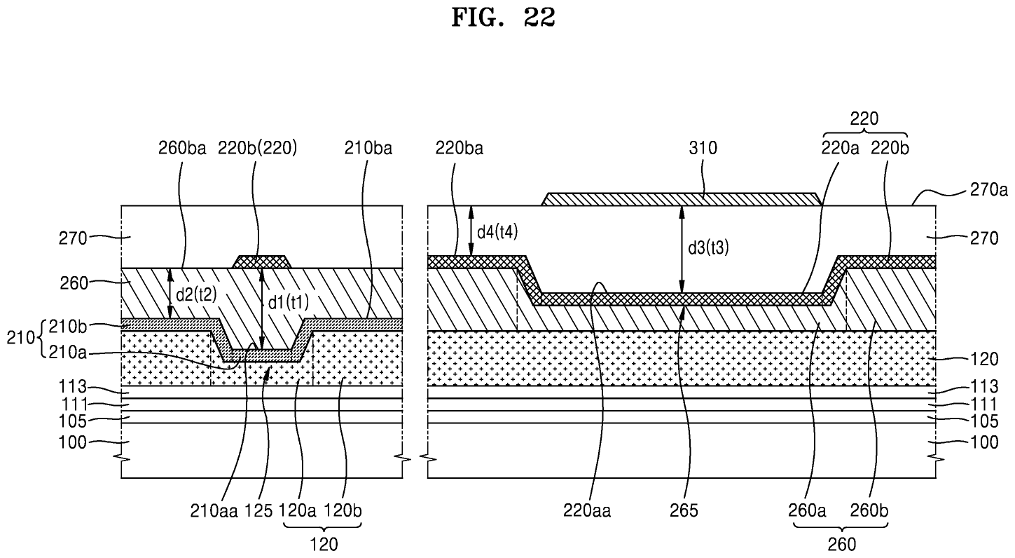

In addition, at least a portion of the second conductive layer 220 formed on the first planarization layer 260 may at least partially overlap the first conductive layer 210 formed below. This will be described later with reference to FIG. 22.

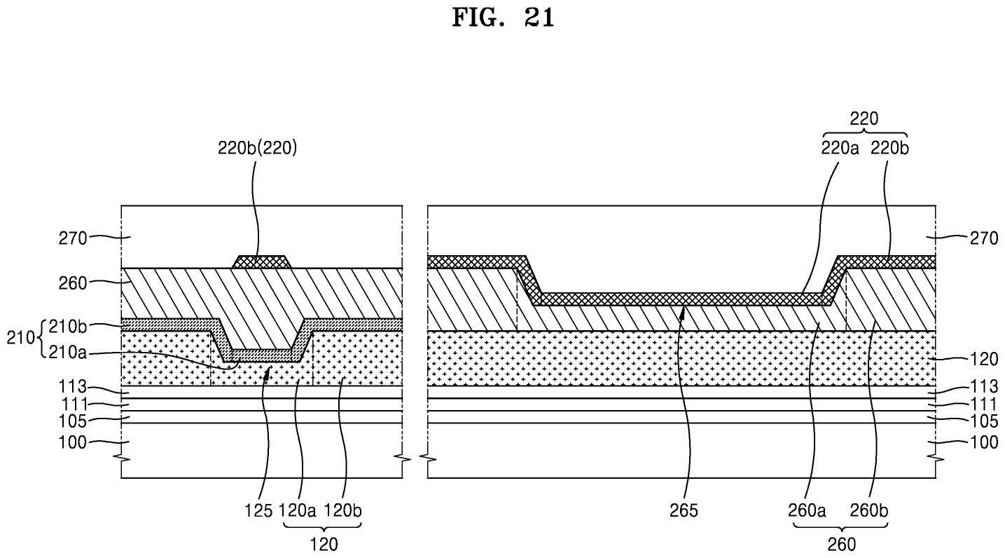

Referring to FIG. 21, after the operation of forming the second conductive layer 220 on the first planarization layer 260, an operation of forming the second planarization layer 270 on the second conductive layer 220 may be performed. The second planarization layer 270 may cover an entirety of the second conductive layer 220 and/or the first planarization layer 260.

Referring to FIG. 22, after the operation of forming the second planarization layer 270 on the second conductive layer 220, an operation of forming the pixel electrode 310 (e.g., third conductive layer) on the second planarization layer 270 may be performed.

As described above, in addition, at least a portion of the second conductive layer 220 formed on the first planarization layer 260 may at least partially overlap the first conductive layer 210 formed below, to define a first overlapping area. In more detail, at least a portion of the 2-2 conductive layer 220b of the second conductive layer 220 formed on the first planarization layer 260, may at least partially overlap the 1-1 conductive layer 210a of the first conductive layer 210 formed between the interlayer insulating layer 120 and the first planarization layer 260.

Since the first groove 125 is formed in the interlayer insulating layer 120, and the 1-1 conductive layer 210a of the first conductive layer 210 is formed in the first groove 125, the first distance d1 from the upper surface 210aa of the 1-1 conductive layer 210a to the upper surface 260ba of the first planarization layer 260, may be greater than the second distance d2 from the upper surface 210ba of the 1-2 conductive layer 210b to the upper surface 260ba of the first planarization layer 260, in a direction vertical to the substrate 100.

In addition, since the first groove 125 is formed in the interlayer insulating layer 120 and recessed in a direction away from the second conductive layer 220, and the 1-1 conductive layer 210a of the first conductive layer 210 is formed in the first groove 125, the first thickness t1 of the first planarization layer 260 at the 1-1 conductive layer 210a may be greater than the second thickness t2 of the first planarization layer 260 at the 1-2 conductive layer 210b.

Since the first groove 125 is formed in the interlayer insulating layer 120, and the 1-1 conductive layer 210a of the first conductive layer 210 is formed in the first groove 125, a distance between the 1-1 conductive layer 210a and the 2-2 conductive layer 220b may be increased. Since a distance between the 1-1 conductive layer 210a and the 2-2 conductive layer 220b is increased, parasitic capacitance may be prevented or reduced from being formed between the 1-1 conductive layer 210a and the 2-2 conductive layer 220b, and RC-delay may be prevented or reduced from increasing.

In other words, a distance between the 1-1 conductive layer 210a and the 2-2 conductive layer 220b is increased as the first groove 125 is formed in the interlayer insulating layer 120 at the first overlapping area where the 2-2 conductive layer 220b of the second conductive layer 220 and the 1-1 conductive layer 210a of the first conductive layer 210 overlap each other. Thus, parasitic capacitance may be prevented or reduced from being formed between the 1-1 conductive layer 210a and the 2-2 conductive layer 220b, and RC-delay may be prevented or reduced from increasing.

At least a portion of the pixel electrode 310 formed on the second planarization layer 270 may at least partially overlap the second conductive layer 220 formed below, to define a second overlapping area. In more detail, at least a portion of the pixel electrode 310 formed on the second planarization layer 270 may at least partially overlap the 2-1 conductive layer 220a of the second conductive layer 220 formed between the first planarization layer 260 and the second planarization layer 270.

Since the second groove 265 is formed in the first planarization layer 260, and the 2-1 conductive layer 220a of the second conductive layer 220 is formed in the second groove 265, the third distance d3 from the upper surface 220aa of the 2-1 conductive layer 220a to the upper surface 270a of the second planarization layer 270 may be greater than the fourth distance d4 from the upper surface 220ba of the 2-2 conductive layer 220b to the upper surface 270a of the second planarization layer 270, in a direction vertical to the substrate 100.

In addition, since the second groove 265 is formed in the first planarization layer 260 and recessed in a direction away from the third conductive layer (e.g., the pixel electrode 310), and the 2-1 conductive layer 220a of the second conductive layer 220 is formed in the second groove 265, the third thickness t3 of the second planarization layer 270 at the 2-1 conductive layer 220a may be greater than the fourth thickness t4 of the second planarization layer 270 at the 2-2 conductive layer 220b.

Since the second groove 265 is formed in the first planarization layer 260, and the 2-1 conductive layer 220a of the second conductive layer 220 is formed in the second groove 265, a distance between the 2-1 conductive layer 220a and the pixel electrode 310 may be increased. Since a distance between the 2-1 conductive layer 220a and the pixel electrode 310 is increased, parasitic capacitance may be prevented or reduced from being formed between the 2-1 conductive layer 220a and the pixel electrode 310, and RC-delay may be prevented or reduced from increasing.

In other words, a distance between the 2-1 conductive layer 220a and the pixel electrode 310 is increased as the second groove 265 is formed in the first planarization layer 260 at the second overlapping area where the pixel electrode 310 and the 2-1 conductive layer 220a of the second conductive layer 220 overlap each other. Thus, parasitic capacitance may be prevented or reduced from being formed between the 2-1 conductive layer 220a and the pixel electrode 310, and RC-delay may be prevented or reduced from increasing.

By using the first halftone mask 500, the first groove 125 may be formed in the interlayer insulating layer 120 without adding a mask during processes. In addition, by using the second halftone mask 600, the second groove 265 may be formed in the first planarization layer 260 without adding a mask during processes.

According to one or more of the above-described embodiments, parasitic capacitance may be prevented or reduced from occurring between wires in different layers and facing each other to define an overlapping area. However, the disclosure is not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
an insulating layer comprising a first portion defining a first groove and a second portion which is adjacent to the first portion; and
in order from the insulating layer:
a first conductive layer comprising a first conductive pattern in the first groove of the insulating layer and a second conductive pattern which is on the second portion of the insulating layer;
a first planarization layer comprising a third portion defining a second groove and a fourth portion which is adjacent to the third portion; and
a second conductive layer comprising a third conductive pattern in the second groove of the first planarization layer and a fourth conductive pattern on the fourth portion of the first planarization layer.

2. The display apparatus of claim 1, wherein at the first groove of the insulating layer, the first conductive pattern of the first conductive layer faces the fourth conductive pattern of the second conductive layer, with the first planarization layer therebetween.

3. The display apparatus of claim 1, wherein the first conductive pattern of the first conductive layer and the second conductive pattern of the first conductive layer are integral with each other.

4. The display apparatus of claim 1, wherein the third conductive pattern of the second conductive layer and the fourth conductive pattern of the second conductive layer are integral with each other.

5. The display apparatus of claim 1, wherein
each of the first conductive pattern of the first conductive layer, the second conductive pattern of the first conductive layer and the first planarization layer has an upper surface, and
a distance from the upper surface of the first conductive pattern of the first conductive layer to the upper surface of the first planarization layer, is greater than a distance from the upper surface of the second conductive pattern of the first conductive layer to the upper surface of the first planarization layer.

6. The display apparatus of claim 1, further comprising in order from the insulating layer:
the second conductive layer;
a second planarization layer; and
a third conductive layer.

7. The display apparatus of claim 6, wherein at the second groove of the first planarization layer, the third conductive pattern of the second conductive layer faces the third conductive layer with the second planarization layer therebetween.

8. The display apparatus of claim 6, wherein
each of the third conductive pattern of the second conductive layer, the fourth conductive pattern of the second conductive layer and the second planarization layer has an upper surface, and
a distance from the upper surface of the third conductive pattern of the second conductive layer to the upper surface of the second planarization layer, is greater than a distance from the upper surface of the fourth conductive pattern of the second conductive layer to the upper surface of the second planarization layer.

9. The display apparatus of claim 1, wherein the first groove and the second groove are spaced apart from each other in a direction along the insulating layer.

10. The display apparatus of claim 1, further comprising:
a first transistor comprising a first semiconductor layer and a first electrode which overlaps the first semiconductor layer; and
a capacitor comprising the first electrode and a second electrode which overlaps the first electrode.

11. The display apparatus of claim 10, wherein the second electrode of the capacitor faces the first planarization layer with the insulating layer therebetween.

12. The display apparatus of claim 10, further comprising a second transistor spaced apart from the first transistor in a direction along the insulating layer, and comprising:
a second semiconductor layer in a different layer than the first semiconductor layer of the first transistor, and
a third electrode which overlaps the second semiconductor layer and is in a different layer than the second electrode of the capacitor.

13. The display apparatus of claim 12, wherein the third electrode of the second transistor faces the first planarization layer with the insulating layer therebetween.

14. The display apparatus of claim 12, wherein the first semiconductor layer of the first transistor and the second semiconductor layer of the second transistor comprise different materials from each other.

15. The display apparatus of claim 1, wherein in a direction along the insulating layer:
the first conductive layer extends in a first direction,
the second conductive layer extends in a second direction crossing the first direction, and
at the first groove of the insulating layer, the first conductive layer which extends in the first direction faces the second conductive layer which extends in the second direction, with the first planarization layer therebetween.

16. A method of providing a display apparatus, the method comprising:
providing an insulating layer in which is defined a first groove; and
providing in order from the insulating layer:
a first conductive layer corresponding to the first groove of the insulating layer;
a first planarization layer; and
a second conductive layer corresponding to the first groove of the insulating layer which correspond to the first conductive layer.

17. The method of claim 16, wherein the providing of the insulating layer comprises:
providing a photoresist pattern on the insulating layer;
providing the photoresist pattern exposed to light by using a first halftone mask;
providing development of the photoresist pattern which is exposed to the light by using the first halftone mask;
providing etching of the photoresist pattern which is developed and the insulating layer, to define the first groove of the insulating layer; and
providing removal of the photoresist pattern which is etched, from the insulating layer which has the first groove defined therein.

18. The method of claim 16, wherein the providing of the first planarization layer comprises:
providing the first planarization layer exposed to light by using a second halftone mask; and
providing development of the first planarization layer which is exposed to the light by using the second halftone mask, to define a second groove of the first planarization layer.

19. The method of claim 16, wherein the first conductive layer is both in the first groove of the insulating layer and on a portion of the insulating layer which is adjacent to the first groove.

20. The method of claim 18, wherein the second conductive layer is both in the second groove of the first planarization layer and on a portion of the first planarization layer which is adjacent to the second groove.

21. The method of claim 16, wherein at the first groove of the insulating layer, the first conductive layer faces the second conductive layer, with the first planarization layer therebetween.

22. The method of claim 16, wherein the first conductive layer comprises:
a first conductive pattern in the first groove of the insulating layer, and
a second conductive pattern which extends from the first conductive pattern to be on a portion of the insulating layer which is adjacent to the first groove.

23. The method of claim 18, wherein the second conductive layer comprises:
a third conductive pattern in the second groove of the first planarization layer, and
a fourth conductive pattern which extends from the third conductive pattern to be on a portion of the first planarization layer which is adjacent to the second groove

24. The method of claim 16, wherein
each of the first conductive layer and the first planarization layer has an upper surface, and
a distance from the upper surface of the first conductive layer at the first groove, to the upper surface of the first planarization layer, is greater than a distance from the upper surface of the first conductive layer adjacent to the first groove, to the upper surface of the first planarization layer.

25. The method of claim 18, further comprising providing in order from the insulating layer:
a second planarization layer facing the second conductive layer, and
a third conductive layer.

26. The method of claim 25, wherein at the second groove of the first planarization layer, the second conductive layer overlaps the third conductive layer.

27. The method of claim 25, wherein
each of the second conductive layer and the second planarization layer has an upper surface, and
a distance from the upper surface of the second conductive layer at the second groove, to the upper surface of the second planarization layer, is greater than a distance from the upper surface of the second conductive layer adjacent to the second groove, to the upper surface of the second planarization layer.

28. The method of claim 18, wherein the first groove and the second groove are spaced apart from each other in a direction along the insulating layer.

29. The method of claim 16, wherein
the first conductive layer extends in a first direction,
the second conductive layer extends in a second direction crossing the first direction, and
at the first groove of the insulating layer, the first conductive layer which extends in the first direction faces the second conductive layer which extends in the second direction, with the first planarization layer therebetween.

30. The method of claim 16, further comprising providing a transistor,
wherein the providing of the first planarization layer disposes the first planarization covering the transistor.
